(19) United States
(12) Patent Application Publication
(10) Pub. No.: US 2026/0020257 A1
(43) Pub. Date: Jan. 15, 2026

(54) THREE-DIMENSIONAL SEMICONDUCTOR DEVICES AND MANUFACTURING METHODS THEREOF

(71) Applicant: Yangtze Memory Technologies Holding Co., Ltd., Wuhan (CN)

(72) Inventors: Wei LIU, Wuhan (CN); Zongliang HUO, Wuhan (CN); Shiqi HUANG, Wuhan (CN); Yanhong WANG, Wuhan (CN); Liang CHEN, Wuhan (CN)

(21) Appl. No.: 19/338,014

(22) Filed: Sep. 24, 2025

Related U.S. Application Data
(63) Continuation of application No. PCT/CN2025/101369, filed on Jun. 17, 2025.

(30) Foreign Application Priority Data
Jun. 26, 2024 (CN) 202410842552.0
Jun. 12, 2025 (CN) 202510787372.1

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2225/06541; H01L 2924/1431; H01L 2924/1436

(57) ABSTRACT

Systems, devices, and manufacturing methods of a semiconductor device are provided. In one aspect, a semiconductor device includes a first semiconductor structure and a second semiconductor structure. The first semiconductor structure includes a memory array. The memory array includes a first memory subarray and a second memory subarray stacked along a first direction. A first row of memory cells of the first memory subarray and a first row of memory cells of the second memory subarray are coupled to a same bit line. The same bit line is between the first memory subarray and the second memory subarray along the first direction. The second semiconductor structure includes a control circuitry coupled to the memory array. The semiconductor device includes a second via structure that is coupled to the pad-out structure of the second semiconductor structure through the first via structure and the interconnection structure.

### CROSS-REFERENCE TO RELATED APPLICATIONS

This application is a continuation of International Application No. PCT/CN2025/101369, filed on Jun. 17, 2025, which claims priority to Chinese Patent Application No. 202410842552.0, filed on Jun. 26, 2024 and claims priority to Chinese Patent Application No. 202510787372.1, filed on Jun. 12, 2025. All of the aforementioned patent applications are hereby incorporated by reference in their entireties.

### TECHNICAL FIELD

The present disclosure relates to semiconductor devices and fabrication processes for semiconductor devices.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for three-dimensional (3D) semiconductor devices with super vias extending through a plurality of conductive layers and stacked memory subarrays that share a same bit line.

One aspect of the present disclosure features a semiconductor device, including a first semiconductor structure including a memory array, the memory array including a first memory subarray and a second memory subarray stacked along a first direction, a first row of memory cells of the first memory subarray and a first row of memory cells of the second memory subarray being coupled to a same bit line, the same bit line being between the first row of memory cells of the first memory subarray and the first row of memory cells of the second memory subarray along the first direction; a second semiconductor structure stacked with the first semiconductor structure along the first direction, where the second semiconductor structure includes a control circuitry coupled to the memory array, an interconnection structure, a pad-out structure, and a first via structure coupling the interconnection structure to the pad-out structure, the control circuitry being between the interconnection structure and the pad-out structure along a first direction; and a second via structure extending through the first semiconductor structure, the second via structure being coupled to the pad-out structure of the second semiconductor structure through the first via structure and the interconnection structure.

In some implementations, the second via structure extends into the second semiconductor structure and contacts the interconnection structure.

In some implementations, the first memory subarray includes a plurality of first memory cells, the second memory subarray includes a plurality of second memory cells, a first memory cell of the plurality of first memory cells is aligned with a corresponding second memory cell of the plurality of second memory cells along the first direction, each of the first memory cell and the corresponding second memory cell extends along the first direction and includes a transistor and a capacitor, and the transistor is closer to the same bit line than the capacitor along the first direction.

In some implementations, the transistor includes a semiconductor body extending along the first direction, and the semiconductor body includes a metal oxide semiconductor material.

In some implementations, the transistor further includes a first terminal, a second terminal, and a gate terminal, and the first terminal is on a first end of the semiconductor body and in contact with the bit line, and the second terminal is on a second end of the semiconductor body and in contact with the capacitor, and the gate terminal is on at least one side of the semiconductor body between the first end and the second end of the semiconductor body.

In some implementations, the second via structure includes a plurality of portions each extending along the first direction, the plurality of portions are arranged along a second direction different from the first direction and separated by an inter-dielectric material, and the interconnection structure includes a plurality of conductive lines, and where first ends of the plurality of portions of the second via structure are coupled to a same connection structure, and second ends of the plurality of portions of the second via structure are coupled to a same conductive line of the plurality of conductive lines of the interconnection structure.

In some implementations, a pitch of the plurality of portions of the second via structure is smaller than or equal to 1 μm along the second direction.

In some implementations, a size of a portion of the plurality of portions of the second via structure is smaller than or equal to 0.5 μm along the second direction.

In some implementations, the interconnection structure includes a first conductive layer, at least one second conductive layer, and a third conductive layer, the at least one second conductive layer being between the first conductive layer and the third conductive layer along the first direction, where a first end of the first via structure is connected to the first conductive layer, a second end of the first via structure is connected to the third conductive layer, and a conductive material of the first via structure is isolated from the at least one second conductive layer by a dielectric material.

In some implementations, a size of the first via structure is smaller than or equal to 0.5 m along a second direction.

In some implementations, the first via structure includes a plurality of portions arranged along a second direction, and a pitch of the plurality of portions of the first via structure is smaller than or equal to 1 μm along a second direction.

In some implementations, the second semiconductor structure includes a plurality of first via structures including the first via structure and additional first via structure, the additional first via structure couples the interconnection structure to the control circuitry, a first end of the additional first via structure is aligned with the first end of the first via structure, and a second end of the additional first via structure is aligned with the second end of the first via structure.

In some implementations, the second semiconductor structure includes a substrate, an interconnection layer and a device layer, the interconnection layer includes the interconnection structure, and the device layer includes the control circuitry, where the interconnection layer and the device layer are on a first side of the substrate, the pad-out structure is on a second side of the substrate, the first side and the second side being opposite to each other along the first direction, where a through-via structure includes: a first segment extending in the interconnection layer and being coupled to the second via structure through the interconnection structure, a second segment extending in the device layer and being coupled to the first segment, and a third segment extending in the substrate and being coupled to the second segment and the pad-out structure on opposite ends of the third segment along the first direction, the second segment being between the first segment and the third segment along the first direction.

In some implementations, a size of the second via structure is smaller than or equal to 0.5 m along a second direction different from the first direction.

In some implementations, the second via structure includes tungsten (W).

In some implementations, the second semiconductor structure includes a first dielectric layer at a surface of the second semiconductor structure, and the first semiconductor structure includes a second dielectric layer at a surface of the second semiconductor structure, where the first dielectric layer is in contact with the second dielectric layer.

In some implementations, the memory array of the first semiconductor structure is on the interconnection structure of the second semiconductor structure, and the memory array is coupled to the interconnection structure through a conductive via, and where the conductive via has a first end coupled to the memory array and a second end coupled to the interconnection structure, and a size of the first end of the conductive via along a second direction different from the first direction is greater than a size of the second end of the conductive via.

In some implementations, the second semiconductor structure includes one or more first contact structures through a first dielectric layer along the first direction and isolated from each other in the first dielectric layer, and the first semiconductor structure includes one or more second contact structures through a second dielectric layer along the first direction and isolated from each other in the second dielectric layer, where, along the first direction, the first dielectric layer is in contact with the second dielectric layer, and at least one of the one or more first contact structures is in contact with at least one of the one or more second contact structures, and where the memory array is coupled to the control circuitry through at least one of the one or more first contact structures and at least one of the one or more second contact structures.

In some implementations, the second semiconductor structure is coupled to the first semiconductor structure through at least one contact structure, and the at least one contact structure includes at least one of a bonding pad, a solder bump, a micro-bump, or a pillar.

In some implementations, the memory array is a first memory array, and the first semiconductor structure includes a second memory array, where the control circuitry includes a first circuitry and a second circuitry, the first circuitry is coupled to the first memory array and configured to control the first memory array, and the second circuitry is coupled to the first memory array and configured to control the first memory array.

Another aspect of the present disclosure features a semiconductor device including: a plurality of memory devices sequentially stacked along a first direction, where a memory device of the plurality of memory devices includes a first pad-out structure at a first surface and a second pad-out structure at a second surface opposite to the first surface along a first direction, where the memory device includes: a first semiconductor structure including: (i) a memory array including a first memory subarray and a second memory subarray stacked along the first direction, a first row of memory cells of the first memory subarray and a first row of memory cells of the second memory subarray being coupled to a same bit line, the same bit line being between the first row of memory cells of the first memory subarray and the first row of memory cells of the second memory subarray along the first direction, and (ii) the second pad-out structure; and a second semiconductor structure stacked with the second semiconductor structure along the first direction, where the second semiconductor structure includes a control circuitry coupled to the memory array, an interconnection structure, and the first pad-out structure, where the plurality of memory devices are coupled to one another with first pad-out structures being in contact with corresponding second pad-out structures.

In some implementations, the second semiconductor structure includes a first via structure coupling the interconnection structure to the first pad-out structure, where the memory device of the plurality of memory devices includes: a second via structure extending through the first semiconductor structure and a portion of the second semiconductor structure, the second via structure being coupled to the first via structure through the interconnection structure, and where the first pad-out structure is coupled to the corresponding second pad-out structure through the first via structure and the second via structure.

In some implementations, the second via structure includes a plurality of portions each extending along the first direction, the plurality of portions are arranged along a second direction different from the first direction and separated by an inter-dielectric material, the interconnection structure includes a plurality of conductive lines, and where first ends of the plurality of portions of the second via structure are coupled to a same connection structure, and second ends of the plurality of portions of the second via structure are coupled to a same conductive line of the plurality of conductive lines of the interconnection structure.

In some implementations, the first memory subarray includes a plurality of first memory cells, the second memory subarray includes a plurality of second memory cells, a first memory cell of the plurality of first memory cells is aligned with a corresponding second memory cell of the plurality of second memory cells along the first direction, each of the first memory cell and the corresponding second memory cell extends along the first direction and includes a transistor and a capacitor, and the transistor is closer to the same bit line than the capacitor along the first direction.

In some implementations, the second semiconductor structure includes one or more first contact structures through a first dielectric layer along the first direction and isolated from each other in the first dielectric layer, and the first semiconductor structure includes one or more second contact structures through a second dielectric layer along the first direction and isolated from each other in the second dielectric layer, where, along the first direction, the first dielectric layer is in contact with the second dielectric layer, and at least one of the one or more first contact structures is in contact with a corresponding one of the one or more second contact structures, and where the memory array is coupled to the control circuitry through at least one of the one or more first contact structures and at least one of the one or more second contact structures.

In some implementations, at least one of the first pad-out structures, or the second pad-out structures includes at least one of a bonding pad, a solder bump, a micro-bump, or a pillar.

In some implementations, the semiconductor device includes: a base structure including a circuitry and a base pad-out structure coupled to the circuitry, where the plurality of memory devices are sequentially stacked over the base structure along the first direction, and the plurality of memory devices are coupled to the circuitry of the base structure through the first pad-out structures, the second pad-out structures and the base pad-out structure.

Another aspect of the present disclosure features a method including forming a memory device, the memory device including: a first semiconductor structure including a memory array including a first memory subarray and a second memory subarray stacked along a first direction, a first row of memory cells of the first memory subarray and a first row of memory cells of the second memory subarray being coupled to a same bit line, the same bit line being between the first row of memory cells of the first memory subarray and the first row of memory cells of the second memory subarray along the first direction; and a second semiconductor structure stacked with the first semiconductor structure along the first direction, the second semiconductor structure including a substrate, a control circuitry on a first side of the substrate, an interconnection structure coupled to the control circuitry, and a first part of a through-via structure coupled to the interconnection structure and on the first side of the substrate, the first part of the through-via structure including a first via structure; forming a second via structure extending through the first semiconductor structure, the second via structure being coupled to the first via structure through the interconnection structure; and forming a second part of the through-via structure extending in the substrate and being coupled to the first part of the through-via structure.

In some implementations, the method includes forming a pad-out structure on a second side of the substrate of the second semiconductor structure and coupled to the first via structure, the memory array of the first semiconductor structure being coupled to the pad-out structure through the first via structure and the second via structure.

In some implementations, the method includes: providing a base structure including a plurality of base dies, a base die of the plurality of base dies including a circuitry and a base pad-out structure coupled to the circuitry; and stacking the memory device over the base die with the pad-out structure being in contact with the base pad-out structure.

In some implementations, the memory device is a first memory device, and where the method includes: forming a plurality of memory devices including the first memory device, the plurality of memory devices including first via structures and second via structures, and stacking the plurality of memory devices sequentially on the base die along the first direction, the plurality of memory devices being coupled to one another through first via structures and corresponding second via structures, the plurality of memory devices being coupled to the circuitry of the base structure through the first via structures, the second via structures, and the base pad-out structure.

In some implementations, forming the memory device includes: forming the second semiconductor structure including one or more first contact structures through a first dielectric layer and isolated from each other in the first dielectric layer; forming the first semiconductor structure including one or more second contact structures through a second dielectric layer and isolated from each other in the second dielectric layer; and stacking the second semiconductor structure and the first semiconductor structure along the first direction, the first dielectric layer being in contact with the second dielectric layer, and at least one of the one or more first contact structures being in contact with a corresponding one of the one or more second contact structures, where the memory array is coupled to the control circuitry through at least one of the one or more first contact structures and at least one of the one or more second contact structures.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a side view of a 3D semiconductor device.

FIG. 1B illustrates a schematic view of a cross-section of an example 3D memory die.

FIG. 1C illustrates a schematic view of a cross-section of an example 3D memory die.

FIG. 2A illustrates a plan view of an example of a first semiconductor structure of a memory die.

FIG. 2B illustrates a cross-sectional view of the memory die of FIG. 2A along A-A′ axis.

FIG. 2C is an enlarged view of a region A of the memory die of FIG. 2A.

FIG. 2D is an enlarged view of a region B of the memory die of FIG. 2A.

FIG. 2E illustrates a cross-sectional view of an example of a memory array of a first semiconductor structure.

FIG. 3A illustrates a schematic diagram of stacking two memory dies.

FIG. 3B illustrates a schematic diagram of a semiconductor device with a plurality of stacked memory dies.

FIG. 3C illustrates a cross-sectional view of the semiconductor device of FIG. 3B.

FIG. 4A illustrates a cross-sectional view of another example of a semiconductor device.

FIG. 4B illustrates an enlarged view of a region A of the semiconductor device of FIG. 4A.

FIGS. 5A-5C illustrate schematic diagrams of examples of layouts of control circuits in a second semiconductor structure of a memory die.

FIGS. 6A-6E illustrate cross-sectional views of an example of a semiconductor device during various stages of a manufacturing process.

FIGS. 7A-7C illustrate a die to wafer bonding process of forming a chip package.

FIG. 8 illustrates a flow chart of an example of a method of forming a semiconductor device.

FIG. 9 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

In a chip package (e.g., high bandwidth memory (HBM)), memory dies can be stacked vertically on a base die. The memory can be DRAM dies. The stacked memory devices can share a common interface (e.g., an interposer) for communication with a processor. In some situations, through-silicon-vias (TSVs) can be formed extending vertically through corresponding memory devices to establish communications between the memory devices and the base die. TSVs may take extra lateral space in the memory die, as an aspect ratio of the TSVs need be below some levels for ease of manufacturing. Additionally, in some cases, DRAM memory cells can include a vertical channel (e.g., a 4F² memory cell). However, in the fabrication process of DRAM cells with vertical channels, the formation process for gate structures can be complex. For example, to achieve uniform height of gate structures, multiple deposition and etching process may be required. Further, it can be difficult to punch through the bottom of conductive layers to isolate adjacent gate structures. As feature sizes continue to shrink, process margins for forming word lines can become even tighter. Moreover, due to the 4F² cell configuration, the process margins for forming word lines may be limited by the bit line layout and/or lengths. The limited process margins for word lines may further restrict die size scaling. Therefore, forming a HBM with higher storage density and larger process margins for word lines can be challenging.

Implementations of the present disclosure provide semiconductor devices and methods for forming such semiconductor devices. In some implementations, a semiconductor device includes a first semiconductor structure and a second semiconductor structure that is stacked with the first semiconductor structure. The first semiconductor structure includes a memory array. The memory array includes a first memory subarray and a second memory subarray stacked along a first direction. A first row of memory cells of the first memory subarray and a first row of memory cells of the second memory subarray are coupled to a same bit line. The same bit line is between the first row of memory cells of the first memory subarray and the first row of memory cells of the second memory subarray along the first direction. The second semiconductor structure includes a control circuitry coupled to the memory array, an interconnection structure, a pad-out structure, and a first via structure coupling the interconnection structure to the pad-out structure. The control circuitry is between the interconnection structure and the pad-out structure along a first direction. The semiconductor device includes a second via structure extending through the first semiconductor structure. The second via structure is coupled to the pad-out structure of the second semiconductor structure through the first via structure and the interconnection structure.

Implementations of the present disclosure can provide one or more of the following technical advantages, effect, and/or benefits. For example, the techniques described in the present disclosure can increase storage density and reduce manufacturing complexity for the word lines. In some implementations, two memory cells with vertical channels can be vertically stacked. The stacked memory cells can share a same bit line that is disposed between the two memory cells along the vertical direction. Sharing a bit line by upper and lower memory cells can shorten a bit line length. Shortening the bit line length may decrease resistance-capacitance (RC) constants. The reduction in RC delay can enhance the sensing margin, allowing for faster data operation. The shortened bit line can also allow for a higher array density. On the other hand, for a same bit line length, the process margin for forming word lines can be increased (e.g., doubled), thereby reducing the manufacturing complexity and improving yield.

Further, the techniques can reduce manufacturing costs (e.g., by 20% or more) by introducing super vias. In some implementations, super vias may be formed to replace at least a part of TSVs. Compared to TSVs that may be formed after an array die is bonded to a control die to form a memory die, or after a memory die is bonded to a base die, the super vias can be formed during wafer manufacture process. Compared to copper vias that may couple adjacent conductive layers (e.g., backend metal layers), the super vias can have a greater depth and extend between non-adjacent conductive layers (e.g., between a top metal (TM) layer and a first metal layer (M1)). Therefore, the super vias can form a direct conductive channel between the TM layer and M1 layer, thereby reducing a routing space that may otherwise be occupied by multiple backend metal layers. Additionally, the super vias can be an alternative to TSVs. Compared to TSVs that may require additional fabrication steps, super vias can be formed during the fabrication process of the memory die. For example, the super vias can be formed, at the same time, in both a device region (e.g., for communication within the memory die) and a via region (e.g., for communication with an external die), thereby simplifying the manufacture process and reducing manufacturing costs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

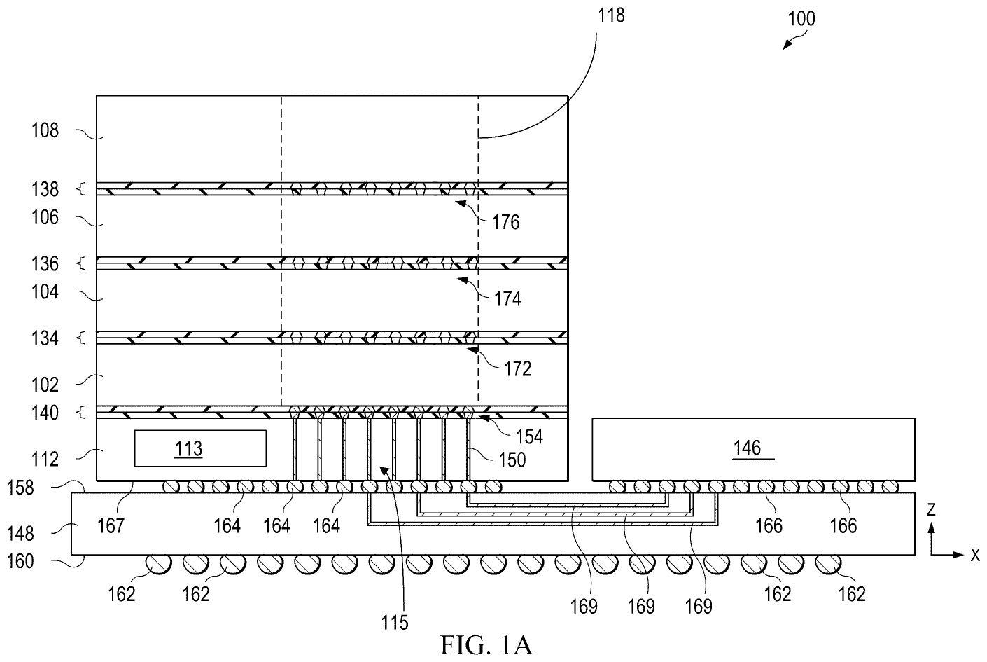

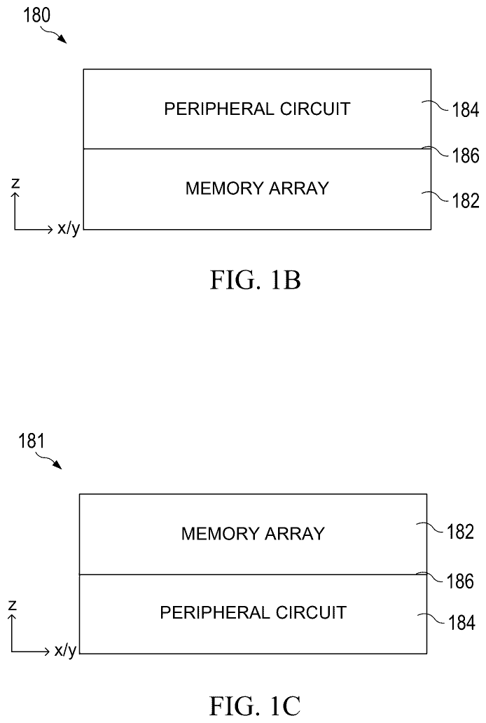

FIG. 1A illustrates a side view of a 3D semiconductor device 100, according to some implementations of the present disclosure. The semiconductor device 100 can be a high bandwidth memory (HBM) device. The semiconductor device 100 can also be referred to as a semiconductor package, or a chip package in the present disclosure. The semiconductor device 100 can include memory dies 102-108, a base die 112, a computing die 146, and an interposer 148. The computing die 146 can also be referred to as a controller or a processor in the present disclosure.

Each of memory dies 102-108 can include at least one memory array, and each memory array can include a plurality of memory cells. The memory dies 102, 104, 106, 108 can be DRAM memory dies, NAND memory dies, ferroelectric memory dies, or any other suitable memory dies. In some implementations, each memory die 102, 104, 106, 108 includes a memory structure and a control structure stacked vertically. The memory structure can include the at least one memory array. The control structure can include control circuits configured to control the operation of the at least one memory array. The control circuit can include, without limitation to, a data buffer/sense amplifier, a column decoder/bit line driver, a row decoder/word line driver, input-output (I/O) circuitry, address decoders, row and column address buffers, read/write control logic, row and column decoders, clock generation and control, Error Correction Code (ECC) logic, power management circuitry, any combination thereof, or any other suitable circuitry. In the present disclosure, the term “control circuit” may be used interchangeable with the term “control circuitry”.

Memory dies 102-108 and base die 112 can be stacked (e.g., sequentially) along the Z direction. Base die 112 and computing die 146 can be integrated on different positions of the interposer 148 along the X direction.

In some implementations, base die 112 includes a base control circuitry 113 that is configured to control the operations of memory dies 102, 104, 106, 108. The base control circuitry 113 of base die 112 can be coupled to control circuits (e.g., in control substructures) of the memory dies 102, 104, 106, 108. The base control circuitry 113 can include at least one of direct access (DA) ports or PHY interface. The DA port can provide testing channels for the memory dies 102-108 in the HBM chip, and the PHY interface can connect the memory devices to the computing die 146. In some implementations, the base control circuitry 113 includes a plurality of transistors (e.g., planar transistors and/or 3D transistors). Trench isolations (e.g., shallow trench isolations (STIs)) and doped regions (e.g., wells, sources, and drains of transistors) can be formed in the base die 112 as well. In some examples, the base control circuitry 113 is formed using complementary metal-oxide-semiconductor (CMOS) technology. In some implementations, the base die 112 includes a through-silicon-contact (TSC) region 115 that has one or more TSCs (also called vias 150) extending through the base die 112 along the Z direction. One ends of the vias 150 can be coupled to the interposer 148 through conductive terminals 164, while the other ends of the vias 150 can be coupled to a lowermost memory die 102 through contact structures 154. The contact structures can also be referred to as conductive contact structures in the present disclosure.

The base die 112 can be coupled to the computing die 146 through the interposer 148. The interposer 148 has a surface 158 and a surface 160. The vias 150 in the base die 112 can be connected to conductive terminals 164 on surface 158 of the interposer 148. The computing die 146 can be connected to conductive terminals 166 on surface 158 of the interposer 148. The semiconductor device 100 can include conductive terminals 162 connected to the surface 160 of the interposer 148. Conductive terminals 164, 166, and/or 162 can be coupled through conductive lines (e.g., conductive lines 169) in the interposer 148. The conductive terminals 162 can be coupled to an external device. In some implementations, the conductive terminals 164, 166, and 162 can be micro bumps, solder bumps, bonding pads, copper pillars, or any other suitable structures. It is to be understood that in practice, base die 112, computing die 146, and interposer 148 can be integrated together using any suitable packaging technology including, for example, Chip-on-Wafer-on-Substrate (CoWoS).

As shown in FIG. 1A, the semiconductor device 100 includes bonding layers (e.g., bonding layers 134, 136, and 138) between adjacent memory dies of memory dies 102-108 and a bonding layer 140 between memory die 102 and base die 112. Each of these bonding layers can include a dielectric material such as silicon oxide. In some implementations, bonding layers 134, 136, 138, and 140 can be referred to as direct bonding layers. Each of bonding layers 134, 136, 138, and 140 can include at least one dielectric material and exclude a conductive bonding contact.

In some implementations, bonding layers 134, 136, 138, and 140 can be referred to as a hybrid bonding layer. A hybrid bonding can include a combination of metal-to-metal bonding and a direct oxide bonding. Bonding layers 134, 136, 138, and 140 can include contact structures 154, 172, 174, 176 and at least one dielectric material isolating the contact structures. Contact structures 154 can be configured to connect memory die 102 and base die 112. Contact structures 172 can be configured to connect memory die 102 and memory die 104. Contact structures 174 can be configured to connect memory die 104 and memory die 106. Contact structures 176 can be configured to connect memory die 106 and memory die 108.

In some implementations, memory die 102 can include an interconnect layer in contact with bonding layer 140. The interconnect layers can include interconnect conductive structures. The interconnect conductive structure can be coupled to base die 112 through contact structures 154 in the bonding layer 140.

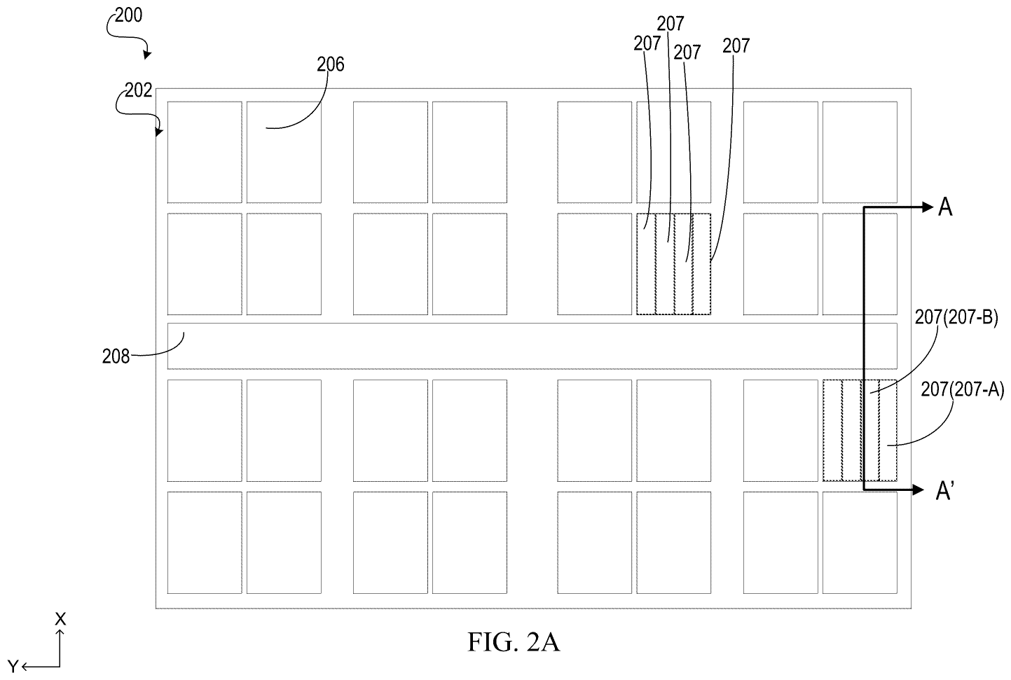

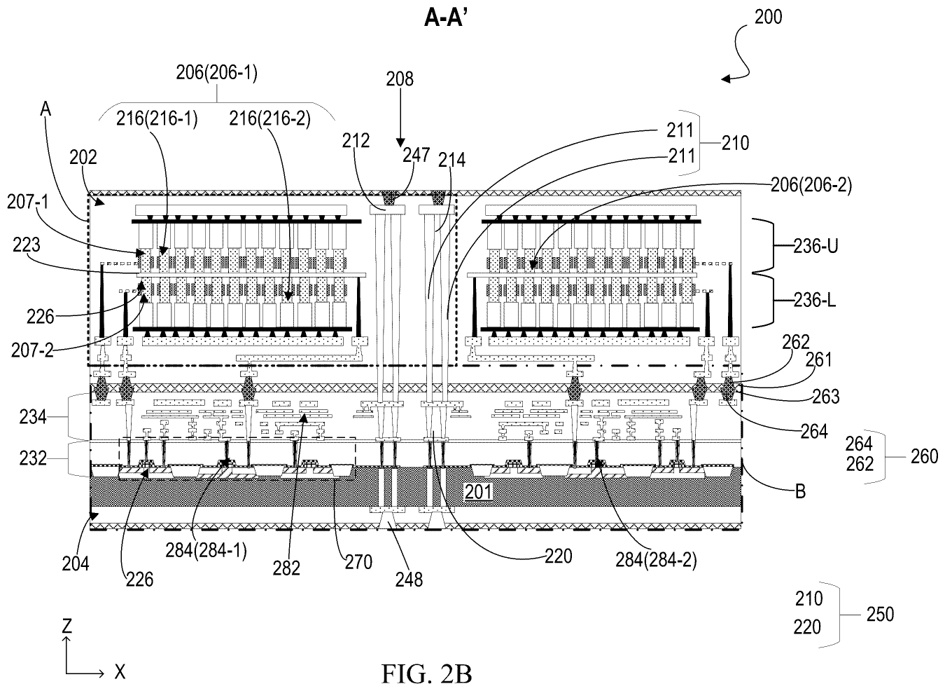

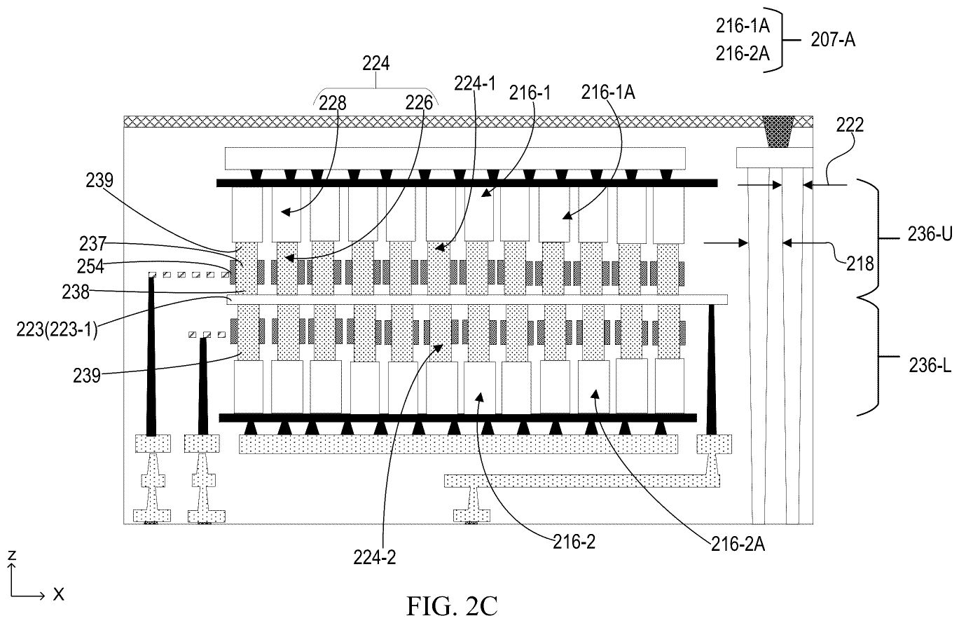

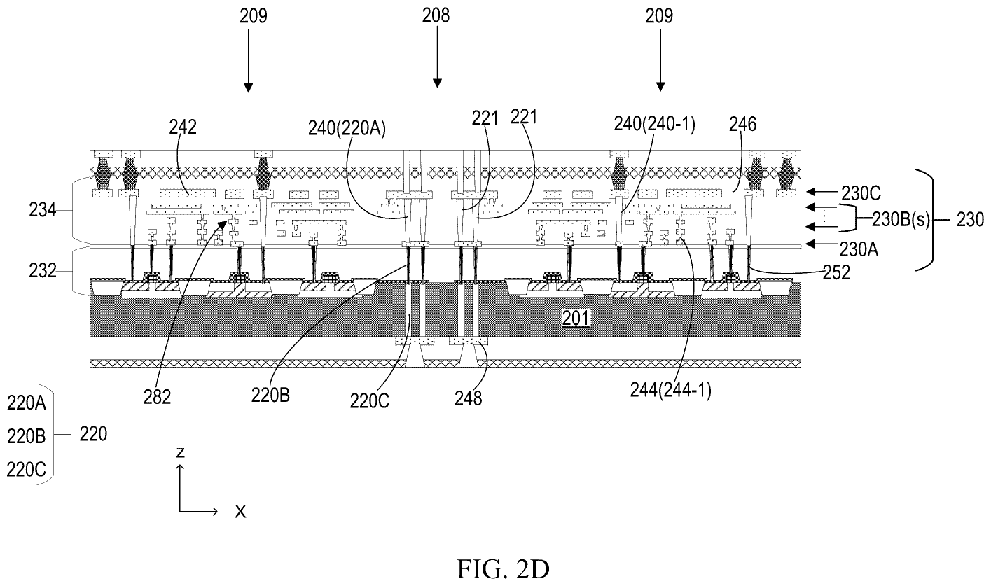

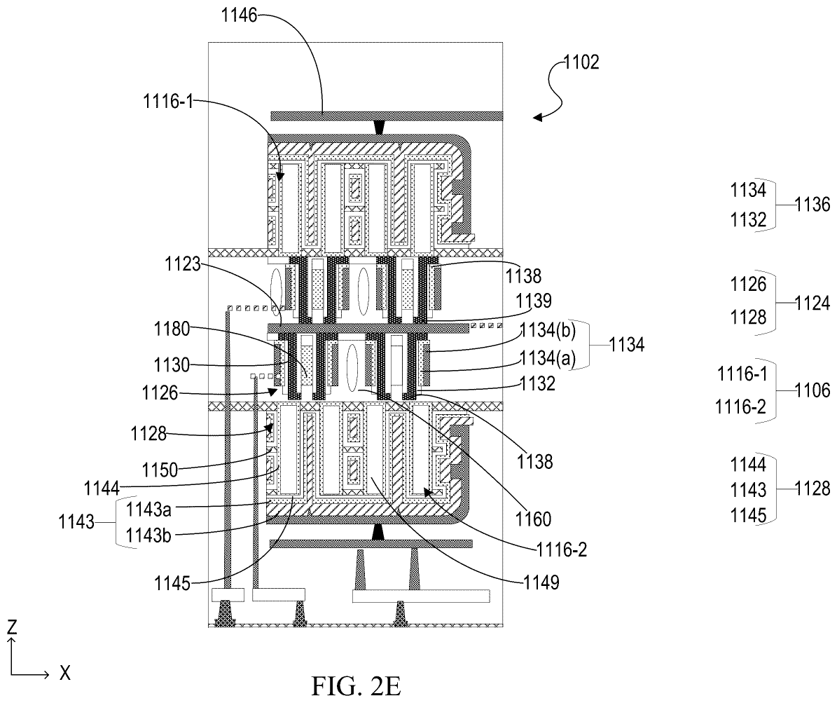

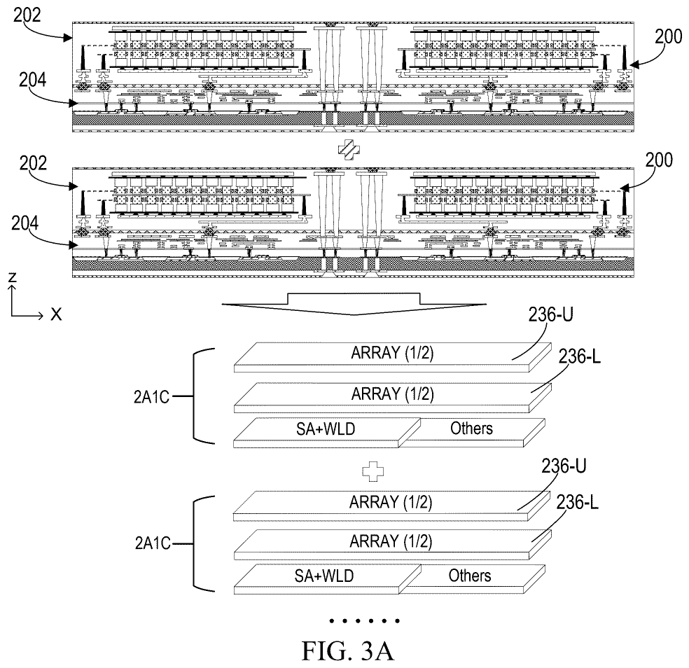

In some implementations, each memory die include a via region 118 that is configured to transfer electrical signals from and to the base die 112. The via region 118 can include first via structures and second via structures that are stacked along Z direction. The first and second via structures are described in greater details below in reference to FIGS. 2A-7C.

In some implementations, as shown in FIG. 1A, memory dies 102-106 can have a reduced thickness (along the Z direction) by having their substrates thinned. The topmost memory die 108 (e.g., the one among memory dice 102-108 that is farthest away from base die 112) may not be thinned. As a result, a thickness of each of memory dice 102-106 can be smaller than a thickness of memory die 108. The thickness of each of memory dice 102-108 can be in any suitable range.

Although not shown, it is to be understood that the interposer 148, the computing die 146, the base die 112, and the memory dies 102, 104, 106, 108 can be stacked sequentially along Z direction, such that the computing die 146 is between the base die 112 and the interposer 148 along Z direction. Similar to the vias 150 of the base die 112, computing die 146 can include through-vias extending through the computing die 146 along the Z direction and being coupled to the interposer 148 through corresponding conductive terminals.

FIG. 1B illustrates a schematic view of a cross-section of an example 3D memory die 180, according to one or more implementations of the present disclosure. 3D memory die 180 represents an example of a bonded chip. The 3D memory die 180 can be implemented as any one of the memory dies 102, 104, 106 and 108 of FIG. 1A. The components of 3D memory die 180 (e.g., memory array and peripheral circuits) can be formed separately on different substrates and then jointed to form a bonded chip. 3D memory die 180 can include a first semiconductor structure 182 including an array of memory cells (e.g., memory array). In some implementations, the memory array includes an array of DRAM memory cells.

The first semiconductor structure 182 can be a DRAM memory device in which memory cells are provided in the form of an array of DRAM memory cells. Memory cells can be organized into pages or fingers, which are then organized into blocks in which each memory cell is electrically coupled to a corresponding bit line (BL) and a corresponding word line (WL). In some implementations, a plane contains a certain number of blocks that are electrically connected through the same bit line. The first semiconductor structure 182 can include one or more planes, and the peripheral circuits that are needed to perform all the read/program (write)/erase operations can be included in a second semiconductor structure 184.

Each DRAM cell can include a transistor and a capacitor coupled to the transistor. DRAM cell can be a 1T1C cell consisting of one transistor and one capacitor. It is understood that DRAM cell may be of any suitable configurations, such as 2T1C cell, 3T1C cell, etc. The transistor can be a MOSFET used to switch a respective DRAM cell. In some implementations, the transistor includes a semiconductor body (the active region in which a channel can form), and a gate structure coupled to the semiconductor body. In some implementations, the gate structure includes a gate electrode and a gate dielectric between the gate electrode and the semiconductor body. In some implementations, the gate dielectric abuts one side of the semiconductor body, and the gate electrode abuts the gate dielectric.

As shown in FIG. 1B, 3D memory die 180 can also include the second semiconductor structure 184 including the peripheral circuits of the memory array of the first semiconductor structure 182. The peripheral circuits (a.k.a. control and sensing circuits) can include any suitable digital, analog, and/or mixed-signal circuits used for facilitating the operations of the memory array. For example, the peripheral circuit can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in second semiconductor structure 184 use CMOS technology, e.g., which can be implemented with logic processes (e.g., technology nodes of 90 nm, 65 nm, 60 nm, 45 nm, 32 nm, 28 nm, etc.). As described above and below in detail, consistent with the scope of the present disclosure, the technology nodes used for fabricating the peripheral circuits in second semiconductor structure 184 can be above 22 nm in order to reduce leakage current, maintain certain voltage levels (e.g., 1.2 V and above), and reduce the cost.

As shown in FIG. 1B, 3D memory die 180 further includes a bonding interface 186 vertically (e.g., along Z direction) between first semiconductor structure 182 and second semiconductor structure 184. In some implementations, the first semiconductor structure 182 and second semiconductor structure 184 can be fabricated separately (and in parallel in some implementations) such that the thermal budget of fabricating one of first semiconductor structure 182 and second semiconductor structure 184 does not limit the processes of fabricating another one of first semiconductor structure 182 and second semiconductor structure 184. Moreover, a large number of interconnects can be formed through bonding interface 186 to make direct, short-distance (e.g., micron-level) electrical connections between first semiconductor structure 182 and second semiconductor structure 184, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 182 and the peripheral circuits in second semiconductor structure 184 can be performed through the interconnects across the bonding interface 186. By vertically (e.g., along Z direction) integrating first semiconductor structure 182 and second semiconductor structure 184, the chip size can be reduced, and the memory cell density can be increased.

It is understood that the relative positions of stacked first semiconductor structure 182 and second semiconductor structure 184 are not limited. FIG. 1C illustrates a schematic view of a cross-section of an example 3D memory die 181, according to one or more implementations of the present disclosure. The 3D memory die 181 can be implemented as any one of the memory dies 102, 104, 106 and 108 of FIG. 1A. Different from 3D memory die 180 of FIG. 1B in which second semiconductor structure 184 including the peripheral circuits is above first semiconductor structure 182 including the memory array, in 3D memory die 181 of FIG. 1C, first semiconductor structure 182 including the memory array is above second semiconductor structure 184 including the peripheral circuits. Nevertheless, bonding interface 186 is formed vertically between first semiconductor structure 182 and second semiconductor structure 184 in 3D memory die 181, and first semiconductor structure 182 and second semiconductor structure 184 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. Data transfer between the memory array in first semiconductor structure 182 and the peripheral circuits in second semiconductor structure 184 can be performed through the interconnects across bonding interface 186. In some implementations, the bonding interface 186 can include a first bonding layer in the first semiconductor structure 182 and a second bonding layer in the second semiconductor structure 184. The first bonding layer can include first conductive structures isolated by a first isolating material (e.g., SiO₂ or other dielectric material). The second bonding layer can include second conductive structures isolated by a second isolating material (e.g., SiO₂ or other dielectric material). The first isolating material and the second isolating material can be same or different, e.g., according to actual fabrication needs. Each of the second conductive structures can correspond to a first conductive structure of the first conductive structures. As such, when the first semiconductor structure 182 and the second semiconductor structure 184 are stacked together, the second conductive structures can be in contact with the corresponding first conductive structures to form conductive bonding (e.g., metal-to-metal bonding) through the bonding interface 186.

FIG. 2A illustrates a plan view of an example of a first semiconductor structure 202 of a memory die 200 according to one or more implementations of the present disclosure. The first semiconductor structure 202 can be implemented as the first semiconductor structure 182 of FIGS. 1B and 1C. As illustrated in FIG. 2A, in some implementations, the first semiconductor structure 202 can include a plurality of memory arrays 206 arranged along lateral directions (e.g., X and Y directions). The first semiconductor structure 202 can further include a via region 208 between the plurality of memory arrays 206. As described in further details below in reference to FIG. 2B, the via region 208 can include via structures that couple the memory arrays 206 to the control circuits of a second semiconductor structure (e.g., the second semiconductor structure 184 of FIGS. 1B and 1C). The via region 208 can be the via region 118 of FIG. 1A. It is to be noted that FIG. 2A is for illustration purpose, and not intended to be construed in a limiting sense. Other arrangements of the memory arrays 206 and/or via region 208 can also be implemented. For example, the via region 208 can be positioned off-center (e.g., as illustrated in FIG. 1A). In another example, the via region 208 can be adjacent to the edge of the memory die 200. In other words, the space between the via region 208 and the edges of the memory die 200 can be free of a memory array 206.

In some implementations, each memory array 206 includes a plurality of pairs 207 of memory cell rows that are arranged along a lateral direction (e.g., Y direction). For example, in the example implementation of FIG. 2A, each memory array 206 can include four pairs 207 of memory cell rows. As described with further details below in reference to FIG. 2B, each pair 207 of memory cell row can include two memory cell rows that are stacked vertically along Z direction. Each of the two memory cell rows can include a plurality of memory cells that are arranged along X direction.

It is to be noted that while each memory array 206 has been illustrated in FIG. 2A as including four pairs 207 of memory cell rows, the memory array 206 can include any other number of pairs. For example, each memory array 206 can include 216 pairs of memory cell rows, 512 pairs of memory cell rows, 1024 pairs of memory cell rows, 2000 pairs of memory cell rows, 4000 pairs of memory cell rows, or any other suitable numbers.

FIG. 2B illustrates a cross-sectional view of the memory die 200 of FIG. 2A along A-A′ axis. FIG. 2C is an enlarged view of region A of the memory die 200 of FIG. 2A. FIG. 2D is an enlarged view of region B of the memory die 200 of FIG. 2A. For ease of description, reference will be made to FIGS. 2B-2D when describing the structure of the memory die 200.

The memory die 200 can include the first semiconductor structure 202 and a second semiconductor structure 204. The second semiconductor structure 204 can be implemented as the second semiconductor structure 184 of FIGS. 1B and 1C. The first semiconductor structure 202 and the second semiconductor structure 204 can be stacked along a vertical direction (e.g., Z direction).

The first semiconductor structure 202 can include a plurality of memory arrays 206. For simplicity, two memory arrays 206 are illustrated in FIG. 2B, which are arranged on opposite sides of the via region 208 along a lateral direction (e.g., X direction). In some implementations, each memory array 206 includes a first memory subarray 216-1 and a second memory subarray 216-2 stacked along Z direction. The first memory subarrays 216-1 from multiple memory arrays 206 can be disposed at a same or similar vertical level. Similar, the second memory subarrays 216-2 from multiple memory arrays 206 can be disposed at a same or similar vertical level. Collectively, the first memory subarrays 216-1 from multiple memory arrays 206 can be referred to as an upper memory layer 236-U, while the second memory subarray 216-2s can be referred to as a lower memory layer 236-L in the present disclosure. As illustrated in FIG. 2B, each memory die 200 can include two memory layers, e.g., the upper memory layer 236-U and the lower memory layer 236-L, that are vertically stacked together along Z direction.

Each memory subarray 216 can include a plurality of rows of memory cells that are arranged along Y direction. Each row of memory cells can include a plurality of memory cells 224 that are arranged along X direction. The memory cells 224 in the first memory subarray 216-1 can be referred to as first memory cells, while the memory cells 224 in the second memory subarray 216-2 can be referred to as second memory cells in the present disclosure.

The memory cells can be a DRAM memory cell with vertical transistors (e.g., 4F² memory cells). Referring to FIG. 2C, in some implementations, each DRAM cell 224 includes a capacitor 228 and at least one transistors 226 coupled to the capacitor 228 (e.g., 1T1C cell, 2T1C cell, 3T1C cell, etc.). The example implementation in FIG. 2B shows 1T1C cells. In some implementations, both the transistor 226 and the capacitor 228 extend along a vertical direction (e.g., Z direction). The transistor 226 can include a semiconductor body 237 extending along Z direction. In some implementations, the semiconductor body 237 includes a metal oxide semiconductor material. In some implementations, the metal oxide semiconductor material includes indium gallium zinc oxide (IGZO), or indium gallium silicon oxide (IGSO), or a combination thereof. Example implementations of a memory cell 224 is described in greater details below in reference to FIG. 2E.

The transistor 226 can further include a first terminal 238, a second terminal 239, and a gate terminal 254. The first terminal 238 (e.g., drain terminal) can be on a first end of the semiconductor body 237 and coupled to a bit line 223, and the second terminal 239 (e.g., source terminal) can be on a second end of the semiconductor body 237 and coupled to the capacitor 228. The gate terminal 254 can be on at least one side of the semiconductor body 237 between the first end and the second end of the semiconductor body 237. Source and drain terminals can be doped with N+ type dopants (e.g., Phosphorus (P) or Arsenic (As)) or P-type dopants (e.g., Boron (B) or Gallium (Ga)) at a desired doping level, or include Silicon Germanium (SiGe). The gate terminal 254 can include a gate dielectric layer and a gate electrode. The gate dielectric can abut at least one side of the semiconductor body 237, while the gate electrode can abut the gate dielectric layer. Based on how many sides of the semiconductor body 237 that a gate terminal 254 can abut to, the gate terminal 254 can be a single-side gate structure, a dual-side gate structure, a triple-side gate structure, or a gate-all-around (GAA) structure. The gate terminal 254 can connect to a word line, or be part of a word line. In some implementations, the first semiconductor structure 202 has no substrate (e.g., silicon substrate).

With continued reference to FIG. 2C, the first memory subarray 216-1 can include a first row 216-1A of first memory cells extending along X direction, and the second memory subarray 216-2 can include a first row 216-2A of second memory cells extending along X direction. The first row 216-1A of the first memory cells can be stacked on and/or aligned with the first row 216-2A of the second memory cells along Z direction. The combination of a row of the first memory cells of the first memory subarray 216-1 and a corresponding row of the second memory cells of the second memory subarray 216-2 can be referred to a pair 207 of memory cell rows in the present disclosure. Each memory array 206 can include a plurality of pairs 207 of memory cell rows (e.g., four pairs 207 are shown in FIG. 2A).

In some implementations, each pair 207 of memory cell rows are coupled to a respective bit line. For example, as illustrated in FIG. 2C, a first row 216-1A of memory cells of the first memory subarray 216-1 and a first row 216-2A of memory cells of the second memory subarray 216-2 can form a first pair 207-A, and the first pair 207-A can be coupled to a same bit line (e.g., a first bit 223-1). The first bit line 223-1 can be between the first row 216-1A of memory cells of the first memory subarray 216-1 and the first row 216-2A of memory cells of the second memory subarray 216-2 along Z direction. Similarly, a second pair 207-B (e.g., as illustrated in FIG. 2A) of memory cell rows can be coupled to a same bit line (e.g., a second bit line). The second bit line can be separated from the first bit line 223-1. Alternatively, in some implementations, two or more pairs 207 of memory cell rows are coupled to a same bit line. Sharing a bit line by upper and lower memory cell rows can shorten a bit line length. Shortening the bit line length may decrease resistance-capacitance (RC) constants. The reduction in RC delay can enhance the sensing margin, allowing for faster data operation. Further, with a same bit line length, the word line processing margin can be improved as described above.

In some implementations, a first memory cell of the plurality of first memory cells is aligned with a corresponding second memory cell of the plurality of second memory cells along Z direction. For example, as illustrated in FIG. 2C, the first memory cell 224-1 can be in the upper memory layer 236-U, while the corresponding second memory cell 224-2 can be in the lower memory layer 236-L. Both the first memory cell 224-1 and the second memory cell 224-2 can be in the first pair 207-A of memory cell rows. The first memory cell 224-1 can be aligned with the corresponding second memory cell 224-2, and the transistor 226 of the first memory cell 224-1 and the transistor 226 of the second memory cell 224-2 can be between the capacitor 228 of the first memory cell 224-1 and the capacitor 228 of the second memory cell 224-2 along Z direction. Here, a first memory cell can be considered to be aligned with a corresponding memory cell when a lateral offset of their central axis is 50% or less, 30% or less, 20% or less, or 5% or less.

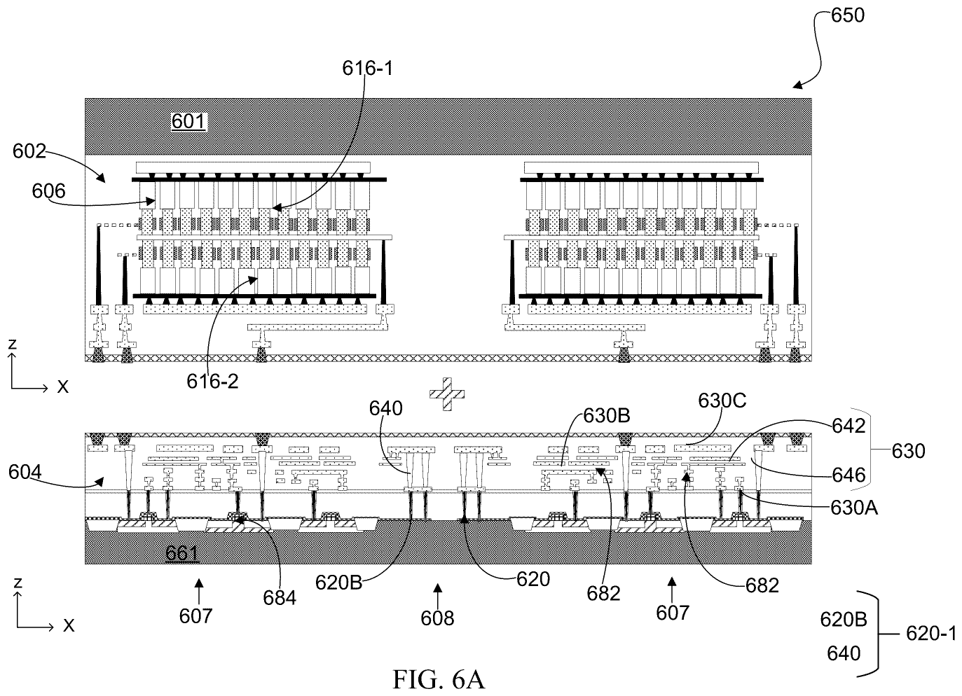

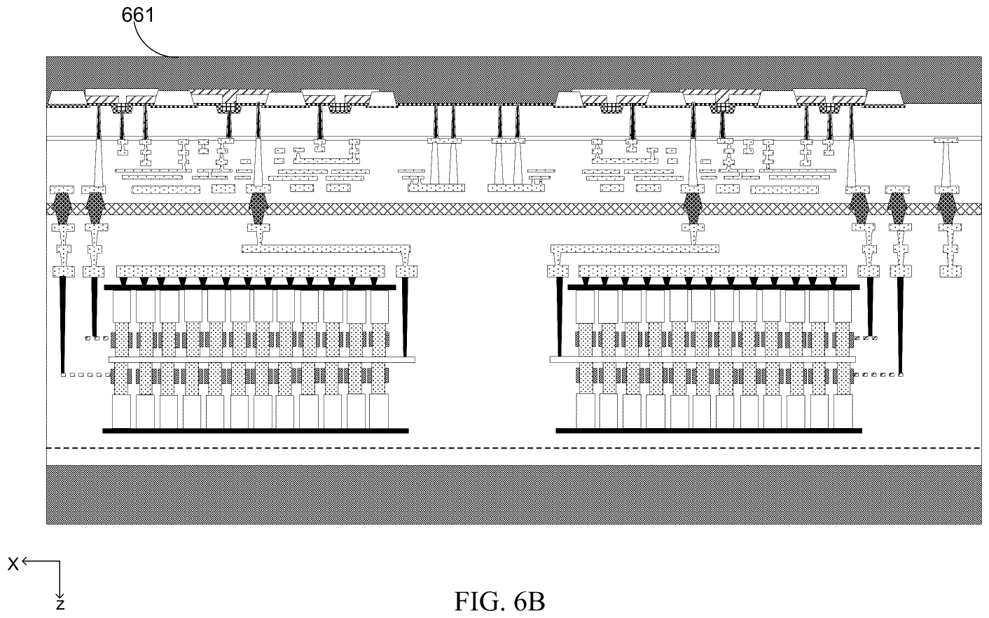

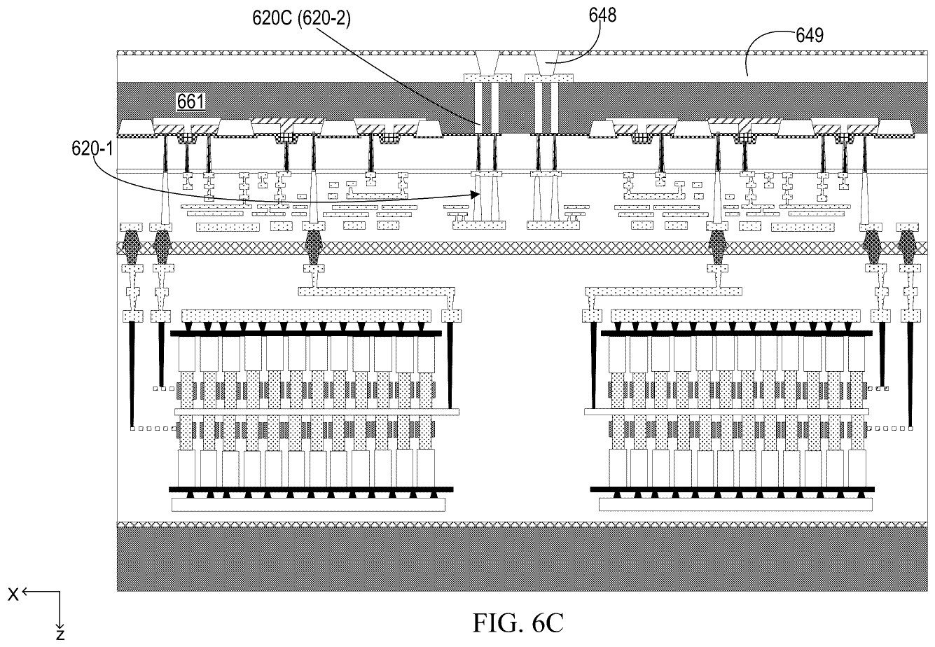

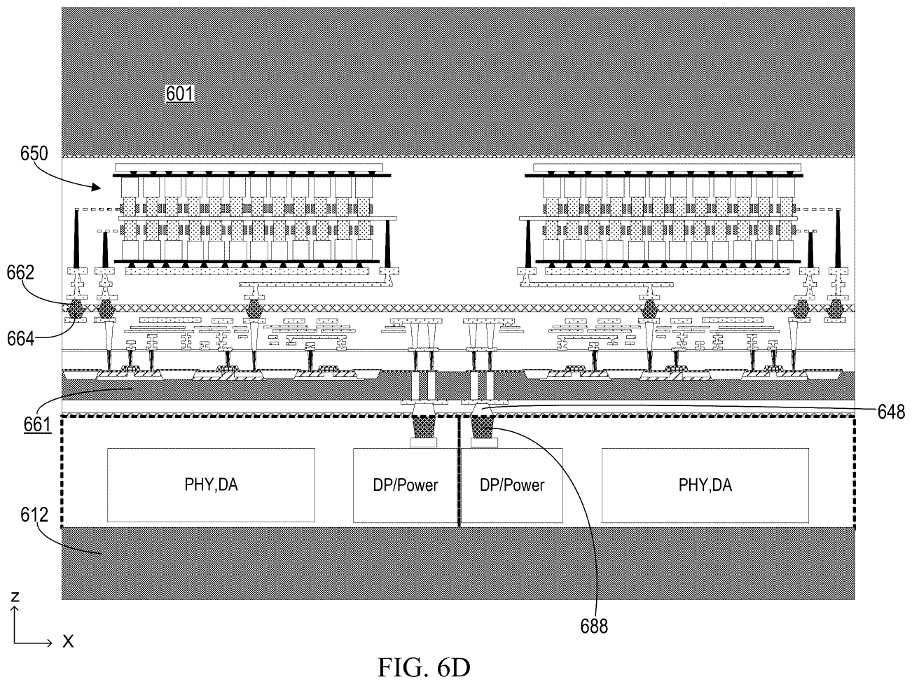

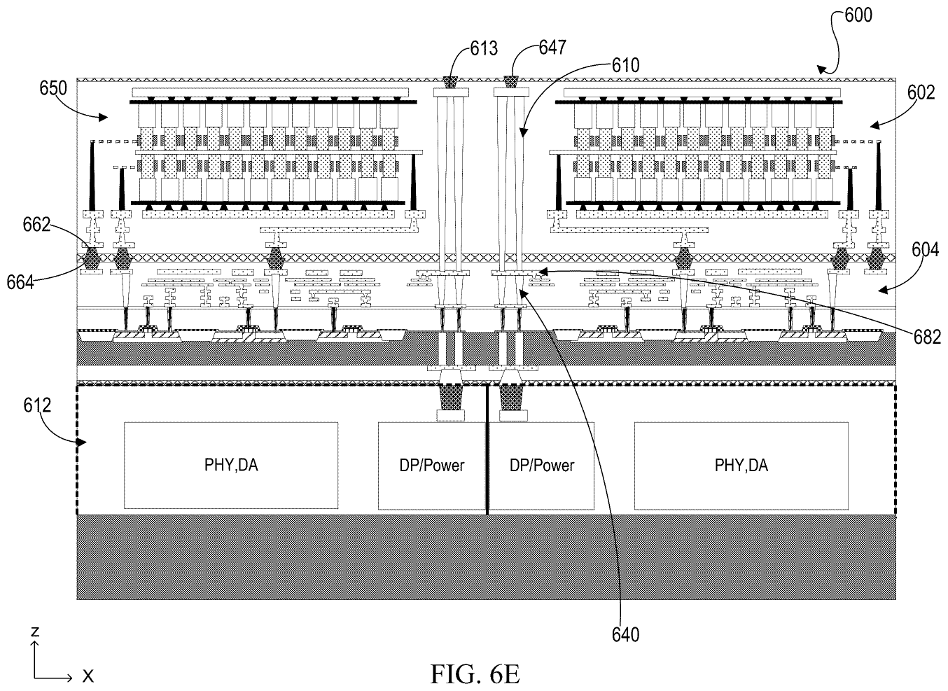

Returning to FIG. 2B, in some implementations, the memory die 200 includes a second via structure 210 extending through the first semiconductor structure 202. The second via structure 210 can be in the via region 208. As noted above, the via region 208 can be between memory arrays 206. The second via structure 210 has a first end (e.g., an upper end) and a second end (e.g., a lower end). The first end of the second via structure 210 can be connected to a connection structure 212, and the second end of the second via structure 210 can extend into the second semiconductor structure 204 and couple to the interconnection structure 282 of the second semiconductor structure 204. The connection structure 212 of the first semiconductor structure 202 can be at a same level or above the memory array 206, and the connection structure 212 can be configured to transfer electrical signals to and from the first semiconductor structure 202. The connection structure 212 can include a plurality of interconnects (also referred to herein as “contacts”), including lateral conductive lines and VIA contacts. The connection structure can further include one or more interlay dielectric (ILD) layers in which the conductive lines and via contacts can form. That is, the connection structure 212 can include conductive lines and via contacts in multiple ILD layers. As described below in further details in reference to FIGS. 6A-6E, the second via structure 210 and/or the connection structure 212 can be formed after bonding the first and second semiconductor structures 202, 204. In some implementations, the connection structure 212 includes first pad-out structures 247, and the first pad-out structures 247 can be bonding pads, solder balls, micro-bumps, or pillars.

In some implementations, a second via structure 210 includes a plurality of portions 211 (e.g., two portions are shown in FIG. 2B for each via structure 210), and each portion 211 extends along Z direction. The plurality of portions 211 can be arranged along X direction and separated by an inter-dielectric material 214. The plurality of portions 211 in each second via structure 210 can be connected to one another in parallel and act like a single via. For example, the first ends (e.g., upper ends) of the plurality of portions 211 of the second via structure 210 can be coupled to a same connection structure 212, while the second ends (e.g., lower ends) of the plurality of portions 211 of the second via structure 210 can be coupled to a same conductive line of the interconnection structure 282 of the second semiconductor structure 204. Without being limited to any particular theory, connecting a plurality of portions 211 in parallel can reduce contact resistance and improve electrical performance.

In some implementations, a pitch 218 of the plurality of portions 211 of the second via structure 210 is 0.5 μm or less, 1 μm or less, 2 μm or less, or 5 μm or less along X direction. In some implementations, a size 222 of an individual portion 211 of the second via structure 210 is 0.3 μm or less, 0.5 μm or less, or 0.7 μm or less along X direction. In the implementations where the second via structure 210 includes only a single portion 211, a size of the second via structure 210 can 0.3 μm or less, 0.5 μm or less, or 0.7 μm or less along X direction. In the implementations where each portion of the second via structure 210 has varying sizes (e.g., the upper ends being bigger than the lower ends), the size of each portion 211 along X direction can refer to an average size of each portion along X direction, or a maximum size of each portion along X direction.

The second via structure 210 can include conductive materials including, but not limited to, W, Co, Cu, Al, doped silicon, silicides, or any combination thereof. In some implementations, the second via structure 210 includes tungsten (W). The inter-dielectric material 214 can be formed with dielectric materials including, but not limited to, silicon oxide, silicon nitride, silicon oxynitride, low-k dielectrics, or any combination thereof.

With continued reference to FIG. 2B, the memory die 200 can further include the second semiconductor structure 204 that is stacked with the first semiconductor structure 202 along Z direction. In some implementations, the second semiconductor structure 204 includes a device layer 232 on a front side of a substrate 201. The device layer 232 can include one or more control circuits 284 coupled to the memory array 206. The control circuits 284 can be peripheral circuits as described above in reference to FIGS. 1B and 1C. The control circuits 284 (a.k.a. control and sensing circuits) can include any suitable digital, analog, and/or mixed-signal circuits used for facilitating the operations of the memory array 206. For example, the control circuit 284 can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions 211 (e.g., a sub-circuit) of the functional circuits mentioned above, or any active or passive components of the circuit (e.g., transistors, diodes, resistors, or capacitors). The control circuits 284 in second semiconductor structure 204 can use CMOS technology, e.g., which can be implemented with logic processes (e.g., technology nodes of 90 nm, 65 nm, 60 nm, 45 nm, 32 nm, 28 nm, etc.). The substrate 201 can include silicon (e.g., single crystalline silicon, c-Si), silicon-germanium (SiGe), gallium arsenide (GaAs), germanium (Ge), silicon-on-insulator (SOI), or any other suitable materials.

In some implementations, the second semiconductor structure 204 includes multiple sets of control circuits 284. Each set of control circuits 284 can be configured to control a corresponding memory array 206. For example, as illustrated in FIG. 2B, the second semiconductor structure 204 can include a first set of control circuits 284-1 and a second set of control circuits 284-2. Different sets of the control circuits 284 can be arranged laterally (e.g., along X direction) and disposed below the corresponding memory array 206. For example, the first set of control circuits 284-1 can be disposed below the first memory array 206-1 and configured to control the first memory array 206-1. Similarly, the second set of control circuits 284-2 can be disposed below the second memory array 206-2 and configured to control the second memory array 206-2. Positing the control circuits 284 below the corresponding memory array 206 can reduce electrical interconnection routings, thereby reducing resistance and improving device performance.

The second semiconductor structure 204 can further include an interconnection layer 234 on the device layer 232. In some implementations, the interconnection layer 234 can be between the first semiconductor structure 202 and the device layer 232 along Z direction. Referring to FIG. 2D, the interconnection layer 234 can include the interconnection structure 282. The interconnection structure 282 can be configured to transfer the electrical signals between the memory array 206 of the first semiconductor structure 202 and the control circuits 284 of the second semiconductor structure 204. In some implementations, the interconnection structure 282 includes a plurality of conductive layers 230 stacked along Z direction. Each conductive layer 230 can include (i) one or more inter layer dielectric (ILD) layers 246, and (ii) lateral conductive lines 242 and/or VIA contacts 244 that extend through the ILD layers 246. The lateral conductive lines 242 and VIA contacts 244 can transfer electrical signals. Adjacent conductive lines 242 or VIA contacts 244 can be isolated by the ILD layers 246.

In some implementations, the interconnection structure 282 includes a first conductive layer 230A, at least one second conductive layer 230B, and a third conductive layer 230C. The at least one second conductive layer 230B can be between the first conductive layer 230A and the third conductive layer 230C along Z direction. For example, the third conductive layer 230C can be a top metal (TM) layer, the first conductive layer 230A can be a first metal (M1) layer, and the at least one second semiconductor layer 230B can be intermediate layers (e.g., a second metal layer (M2), etc.). However, implementations of the first and third conductive layer 230A, 230C are not limited thereto.

In some implementations, a VIA contact 244 connects conductive lines 242 of two adjacent conductive layers 230. For example, as illustrated in FIG. 2D, a first VIA contact 244-1 may connect a conductive line 242 in the first conductive layer 230A (e.g., M1 layer) to a corresponding conductive line 242 in a second conductive layer 230B (e.g., M2 layer). In some examples, a VIA contact 244 may not connect conductive lines 242 in non-adjacent conductive layers 230 that are separated by another conductive layer 230.

In some implementations, the second semiconductor structure 204 includes at least one through-via structure 220. In some implementations, the through-via structure 220 includes multiple segments that are stacked along Z direction. In some implementations, the through-via structure 220 includes (i) a first segment 220A extending in the interconnection layer 234 and being coupled to the second via structure 210 through the interconnection structure 282, (ii) a second segment 220B extending in the device layer 232 and being coupled to the first segment 220A, and (iii) a third segment 220C extending in the substrate 201 and being coupled to the second segment 220B and second pad-out structures 248 on opposite ends of the third segment 220C along Z direction. The second segment 220B can be between the first segment 220A and the third segment 220C along the first direction. The first segment 220A of the through-via structure 220 can be referred to as a first via structure 240 in the present disclosure.

In some implementations, the second semiconductor structure 204 includes one or more first via structures 240. The first via structures 240 can be disposed in the via region 208 and/or a device region 209. The via region 208 can refer to the region that includes the through-via structure 220, while the device region 209 can refer to the region that includes control circuits 284. In some implementations, the via region 208 is at least partially surrounded by the device region 209, as illustrated in FIG. 2D, but not limited thereto. The first via structures 240 in both regions can have the same or similar structures.

Unlike the VIA contact 244, the first via structures 240 can extend through two or more conductive layers 230. In other words, the first via structures 240 can connect the conductive lines 242 in non-adjacent conductive layers 230. For example, as illustrated in FIG. 2D, the first via structure 240-1 can connect the third conductive layer 230C to the first conductive layer 230A. In other words, a first end (e.g., the lower end) of the first via structure 240-1 can be connected to the first conductive layer 230A, and a second end (e.g., the upper end) of the first via structure 240-1 can be connected to the third conductive layer 230C.

It is to be noted that while the example implementation in FIG. 2D illustrates that a first via structure 240 extends all the way from the third conductive layer 230C to the first conductive layer 230A, in some implementations, the first via structures 240 can extend in the interconnection layer 234 at different depths. For example, a first via structure 240 can extend from one of the second conductive layers 230B to the first conductive layer 230A, while another first via structure 240 can extend from the third conductive layer 230C to one of the second conductive layers 230B. In another example, a first via structure 240 can extend from the third conductive layer 230C to a contact 252 (e.g., a source contact, a gate contact, or a drain contact). As noted above, the first via structure 240 differs from the VIA contact 244 primarily in that the first via structure 240 can extend through at least two conductive layers 230 and thus connect conductive lines 242 in non-adjacent conductive layers 230. In some implementations, a height of a first via structure 240 along Z direction is greater than a height of a VIA contact 244 along Z direction. In some implementations, a conductive material (e.g., tungsten, ruthenium) of the first via structure 240 is isolated from conductive lines 242 of the at least one second conductive layers 230B, through which it extends, by a dielectric material (e.g., silicon oxide) in the ILD layer 246.

When first via structures 240 are disposed in the via region 208, the first via structure 240 can be the first segment 220A of the through-via structure 220 and configured to transfer electrical signals between the first and second semiconductor structures, 202, 204. Therefore, the first via structures 240 in the via region 208 can be an alternative of TSVs. When first via structures 240 are disposed in the device region 209, the first via structure 240 can transfer electric signals within the second semiconductor structure 204, e.g., within the interconnection layer 234, or between the interconnection layer 234 and the device layer 232.

In some implementations, the first via structures 240 in the via region 208 and the device region 209 are formed together in a same manufacturing process. Therefore, upper ends of the first via structures 240 in both via region 208 and device region 209 can be aligned. In some implementations, lower ends of the first via structures 240 are also aligned. In some other implementations, lower ends of the first via structures 240 are not aligned, which can extend at different depths.

By forming a first via structure 240 between non-adjacent layers (e.g., between the third conductive layer 230C and the first conductive layer 230A), a vertical interconnection channel can be formed, thereby reducing a routing space that may otherwise be occupied by multiple backend metal layers. Additionally, as noted above, the first via structures 240 can be an alternative to TSVs. Compared to TSVs which require additional fabrication steps, forming first via structures 240 in both device region 209 and via region 208 together can simplify the manufacturing process, thereby reducing manufacturing costs.

In some implementations, as illustrated in FIG. 2D, the second segment 220B of the through-via structure 220 extends in the device layer 232. The second segment 220B of the through-via structure 220 can be formed together with other contacts 252 that connect the source terminals, source terminals, or gate terminals of CMOS transistors to the first conductive layer 230A.

In some implementations, the third segment 220C of the through-via structure 220 extends through the substrate 201 of the second semiconductor structure 204. The third segment 220C of the through-via structure 220 can connect the second segment 220B of the through-via structure 220 to the second pad-out structure 248 that is formed on a backside of the substrate 201. The second pad-out structure 248 can couple the memory die 200 to an external device (e.g., a controller, a base die, or another memory die). As illustrated in FIG. 2D, the control circuits 284 can be between the interconnection structure 282 and the second pad-out structure 248 along Z direction, and the control circuit 284 can be coupled to the second pad-out structure 248 through the third segment 220C of the through-via structure 220.

While the example implementation shown in FIG. 2D depicts that a through-via structure 220 include three segments stacked along Z direction, in some implementations, the through-via structure 220 can include two segments. The first segment 220A of the through-via structure 220 can be first via structures 240, while the second segment of the through-via structure 220 can extend from the first conductive layer 230A directly to the second pad-out structure 248.

In some implementations, the second and third segments of the through-via structure 220, the conductive lines 242, and/or the VIA contacts 244 include conductive materials including, but not limited to, W, Co, Cu, Al, doped silicon, silicides, or any combination thereof. In some implementations, the first via structures 240 include tungsten, ruthenium, or a combination thereof, while the VIA contact 244 includes copper. The ILD layers 246 can be formed with dielectric materials including, but not limited to, silicon oxide, silicon nitride, silicon oxynitride, low-k dielectrics, or any combination thereof.

In some implementations, similar to the second via structure 210, the first via structure 240 includes a plurality of portions 221 arranged along X direction in the via region 208. The plurality of portions 221 can be connected to one another in parallel. In some implementations, a pitch of the plurality of portions 221 of the first via structure 240 is 0.5 μm or less, 1 μm or less, 2 μm or less, or 5 μm or less along X direction. In some implementations, a size of each portion 221 of the plurality of portions 221 of the first via structure 240 is 0.3 μm or less, 0.5 μm or less, or 0.7 μm or less along X direction. In the implementations where the first via structure 240 includes a single portion 221, the size of the first via structure 240 is 0.3 μm or less, 0.5 μm or less, or 0.7 μm or less. In the implementations where each portion of the first via structure 240 has varying sizes (e.g., the upper ends being bigger than the lower ends), the size of the each portion 221 along X direction can refer to an average size of each portion along X direction, or a maximum size of each portion along X direction. In some implementations, each first via structure 240 includes two portions in the via region 208, while the first via structure 240 includes a single portion in the device region 209.

In some implementations, returning to FIG. 2B, both the first via structure 240 and the second via structure 210 are in the via region 208. The second via structure 210 can be stacked on the first via structure 240 along Z direction. The second via structure 210 can be coupled to the second pad-out structure 248 of the second semiconductor structure 204 through at least the first via structure 240 and the interconnection structure 282. In some implementations, a number of the second via structures 210 is equal to a number of the first via structure 240. In some implementations, a number of the second via structures 210 is not equal to a number of the first via structure 240. A combination of the first via structure 240 and the second via structure 210 can be referred to as via structures 250 in the present disclosure.

In some implementations, the first semiconductor structure 202 and the second semiconductor structure 204 are bonded through direct bonding. For example, the second semiconductor structure 204 can include a first dielectric layer 261, and the first semiconductor structure 202 can include a second dielectric layer 263 that is in contact with the first dielectric layer 261. The direct bonding can involve oxide-oxide bonding.

In some implementations, the first semiconductor structure 202 and the second semiconductor structure 204 are bonded through conductive contact structures. For example, the first semiconductor structure 202 can include one or more first contact structures 262 isolated by a first dielectric layer 261. The second semiconductor structure 204 can include one or more second contact structures 264 isolated by a second dielectric layer 263. The first contact structures 262 can be in contact with the one or more second contact structures 264 to form hybrid bonding. In some implementations, the bonding process involves an annealing process to allow copper-to-copper connections between the first contact structures 262 and the corresponding second contact structures 264. Therefore, the first and second contact structures 262, 264 can form a combined contact structure 260, and the interface between the first and second contact structures 262, 264 may not be discernible in a real device.

In some implementations, the first and second contact structures 262, 264 include at least one of a bonding pad, a solder bump, a micro-bump, or a pillar. In some implementations, both the first and second contact structures 262, 264 include bonding pads. The first semiconductor structure 202 and the second semiconductor structure 204 can be bonded through hybrid bonding. A hybrid bonding can include a combination of metal-to-metal bonding (e.g., bonding pads to bonding pads) and a direct oxide bonding. In some implementations, the first contact structures 262 are solder balls, micro-bump or pillars, while the second contact structures 264 are bonding pads. In some implementations, the first contact structures 262 are bonding pads, while the second contact structures 264 are solder balls, micro-bump or pillars.

FIG. 2E illustrates a cross-sectional view of an example of a memory array of a first semiconductor structure 1102. The first semiconductor structure 1102 can be implemented as the first memory structure 202 of FIG. 2B. It is understood that FIG. 2E is for illustrative purposes only and may not necessarily reflect the actual device structure (e.g., interconnections) in practice.

As illustrated in FIG. 2E, the memory array 1106 includes a first memory subarray 1116-1 and a second memory subarray 1116-2 stacked along Z direction. The memory array 1106 can be implemented as the memory array 206 of FIG. 2B. The first memory subarray 1116-1 can be implemented as the first memory subarray 216-1 of FIG. 2B. The second memory subarray 1116-2 can be implemented as the second memory subarray 216-2 of FIG. 2B. The first memory subarray 1116-1 and the second memory subarray 1116-2 can share same bit lines 1123, as described above.

Each memory subarray 1116 includes a plurality of DRAM cells 1124. Each DRAM cell 1124 can include a vertical transistor 1126 and a capacitor 1128 coupled to the vertical transistor 1126. DRAM cell 1124 can be a 1T1C cell consisting of one transistor and one capacitor. It is understood that DRAM cell 1124 may be of any suitable configurations, such as 2T1C cell, 3T1C cell, etc. The vertical transistor 1126 can be a MOSFET used to switch a respective DRAM cell 1124. In some implementations, the vertical transistor 1126 includes a semiconductor body 1130 (the active region in which a channel can form) extending vertically (in the z-direction), and a gate structure 1136 in contact with at least one side of semiconductor body 1130. In a single-gate vertical transistor, the semiconductor body 1130 can have a cuboid shape or a cylinder shape, and the gate structure 1136 can abut a single side of semiconductor body 1130 in a cross-sectional view, e.g., as shown in FIG. 2E. In some implementations, the gate structure 1136 includes a gate electrode 1134 and a gate dielectric 1132 laterally between the gate electrode 1134 and the semiconductor body 1130 in a bit line direction (e.g., in the X direction). In some implementations, the gate dielectric 1132 abuts one side of the semiconductor body 1130, and the gate electrode 1134 abuts the gate dielectric 1132.

In some implementations, the gate electrode 1134 includes multiple conductive layers, such as a W layer over a TiN layer. As illustrated in FIG. 2E, the gate electrode 1134 includes two layers, first gate electrode layer 1134(a) (e.g., TiN) and second gate electrode layer 1134(b) (e.g., W). The first gate electrode layer 1134(a) can have an angled or curved end, e.g., a L-shape in X-Z plane view. The L-shaped gate electrode 1134(a) includes two portions: a first portion extends along Z axis or along an inclined angle relative to the Z axis and a second portion extends along X axis. In addition, the second portion of gate electrode 1134(a), which extends along X axis, can be closer to a bit line or a corresponding capacitor 1128. In some implementations, the second portions of gate electrode 1134(a) in both first memory subarray 1116-1 and second memory array 1116-2 are at upper ends of corresponding semiconductor bodies 130. For example, as illustrated in FIG. 2E, the second portion of gate electrode 1134(a) in the first memory subarray 1116-1 can be at the upper end of the corresponding semiconductor body 1130 and coupled to the corresponding capacitor 1128. The second portion of gate electrode 1134(a) in the second memory subarray 1116-1 can also be at the upper end of the corresponding semiconductor body 1130 but coupled to the bit line 1123. In some implementations, the second portions of gate electrode 1134(a) in both first memory subarray 1116-1 and second memory array 1116-2 are at lower ends of corresponding semiconductor bodies 130.

It is understood that the structure of configuration of a gate structure 1136 is not limited to the example in FIG. 2E and may include any suitable structure and configuration, such as a single-side gate structure, a dual-side gate structure, a triple-side gate structure, or a gate-all-around (GAA) structure.

As shown in FIG. 2E, in some implementations, the semiconductor body 1130 has two ends (the upper end and lower end in FIG. 2E) in the vertical direction (the z-direction), and at least one end extends beyond gate dielectric 1132 in the vertical direction (the z-direction). In some implementations, one end of the semiconductor body 1130 is aligned or coplanar with the respective end of the gate dielectric 1132. In some implementations, both ends (the upper end and lower end) of the semiconductor body 1130 extend beyond the gate electrode 1134, respectively, in the vertical direction (the z-direction). That is, the semiconductor body 1130 can have a larger vertical dimension (e.g., the depth) than that of the gate electrode 1134 (e.g., in the z-direction), and neither the upper end nor the lower end of semiconductor body 1130 may be aligned with the respective end of the gate electrode 1134. Thus, risk of short circuits between the bit lines 1123 and the word lines/gate electrodes 1134 or between the word lines/gate electrodes 1134 and the capacitors 1128 can be reduced. The vertical transistor 1126 can further include a first terminal 1138 and a second terminal 1139, i.e. a source and a drain, disposed at the two opposite ends of the semiconductor body 1130, respectively, in the vertical direction (the z-direction). In some implementations, the first terminal 1138 is coupled to the capacitor 1128, and the second terminal 1139 is coupled to the bit line 1123.

In some implementations, the semiconductor body 1130 includes semiconductor materials, such as indium gallium zinc oxide (IGZO), or indium gallium silicon oxide (IGSO), any other semiconductor materials, or any combinations thereof. Two memory subarrays 1116-1, 1116-2 can be sequentially formed on a same substrate. Terminals 1138 and 1139 can be doped with N+ type dopants (e.g., Phosphorus (P) or Arsenic (As)) or P-type dopants (e.g., Boron (B) or Gallium (Ga)) at a desired doping level, or comprise Silicon Germanium (SiGe).

In some implementations, a silicide layer, such as a metal silicide layer, is formed between the second terminal 1139 of the vertical transistor 1126 and the bit line 1123 as the bit line contact or between the first terminal 1138 of the vertical transistor 1126 and the first electrode of the capacitor 1128 as capacitor contact to reduce the contact resistance. In some implementations, gate dielectric 1132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 1134 includes a conductive material including, but not limited to W, Co, Cu, Al, TiN, TaN, polysilicon, silicide, or any combination thereof. In some implementations, the gate electrode 1134 includes multiple conductive layers, such as a W layer over a TiN layer. In one example, the gate structure 1136 may be a “gate oxide/gate poly” gate in which the gate dielectric 1132 includes silicon oxide and gate electrode 1134 includes doped polysilicon. In another example, gate structure 1136 may be an HKMG in which gate dielectric 1132 includes a high-k dielectric and gate electrode 1134 includes a metal. High-k materials can include any material with a dielectric constant higher than or equal to a threshold value (e.g., 3.9). The gate electrode 1134 can also be referred to as word lines 1134 in the present disclosure.

As described above, since the gate electrode 1134 may be part of a word line or extend in the word line direction (e.g., the Y direction) as a word line, the first semiconductor structure 1102 can also include a plurality of word lines each extending in the word line direction. Each word line 1134 can be coupled to a row of DRAM cells 1124. That is, the bit line 1123 and the word line 1134 can extend in two perpendicular lateral directions, and the semiconductor body 1130 of the vertical transistor 1126 can extend in the vertical direction perpendicular to the two lateral directions in which the bit line 1123 and the word line 1134 extend. Word lines 1134 are in contact with word line contacts. In some implementations, the word lines 1134 include conductive materials including, but not limited to W, Co, Cu, Al, TiN, TaN, polysilicon, silicides, or any combination thereof. In some implementations, the word line 1134 includes multiple conductive layers, such as a W layer over a TiN layer, as shown in FIG. 2E.

In some implementations, as shown in FIG. 2E, the vertical transistor 1126 extends vertically through and contacts the word lines 1134, and the second terminal 1139 of vertical transistor 1126 is in contact with the bit line 1123 (or bit line contact if any). Accordingly, the word lines 1134 and the bit lines 1123 can be disposed in different planes in the vertical direction due to the vertical arrangement of vertical transistor 1126, which simplifies the routing of the word lines 1134 and the bit lines 1123.

In some implementations, the vertical transistors 1126 can be arranged in a mirror-symmetric manner to increase the density of DRAM cells 1124 in the bit line direction (the X direction). As shown in FIG. 2E, two adjacent vertical transistors 1126 in the bit line direction are mirror-symmetric to one another with respect to a trench isolating region 1160. That is, the first semiconductor structure 1102 can include a plurality of trench isolation regions 1160 each extending in the word line direction (the Y direction) in parallel with word lines 1134 and disposed between two adjacent rows of the vertical transistors 1126. In some implementations, the rows of vertical transistors 1126 separated by the trench isolating region 1160 are mirror-symmetric to one another with respect to the trench isolating region 1160. The trench isolating region 1160 can be formed with dielectric materials including, but not limited to, silicon oxide, silicon nitride, silicon oxynitride, low-k dielectrics, or any combination thereof. It is understood that the trench isolating region 1160 may include an air gap each disposed laterally between adjacent transistors. Air gaps may be formed due to the relatively small pitches of vertical transistors 1126 in the bit line direction (e.g., the X direction). On the other hand, the relatively large dielectric constant of air in air gaps (e.g., about 4 times of the dielectric constant of silicon oxide) can improve the insulation effect between vertical transistors 1126 (and rows of DRAM cells 1124) compared with some dielectrics (e.g., silicon oxide). In some implementations, a conductive material (e.g., metal such as W) is filled in a 1180 region between two adjacent semiconductor bodies 130, and the conductive material can be surrounded by the dielectric materials such that it is insulated from the semiconductor bodies 130.

As shown in FIG. 2E, in some implementations, a capacitor 1128 includes a first electrode 1144 coupled to the first terminal 1138 of vertical transistor 1126. In some implementation, the first electrode 1144 is coupled to the first terminal 1138 of vertical transistor 1126 via a capacitor contact. In some implementations, the capacitor contact is an ohmic contact, such as a metal silicide contact, as opposed to a Schottky contact. For example, the capacitor contact may include metal silicides, such as WSi, CoSi, CuSi, AlSi, or any other suitable metal silicides having higher conductivities than doped silicon.

In some implementations, the capacitor 1128 includes a dielectric structure 1149 which can have a pillar shape. The first electrode 1144 covers at least one surface of the dielectric structure 1149. In some implementations, the first portion of the first electrode 1144 is coupled to a first terminal 1138 of a corresponding vertical transistor 1126 via an ohmic contact (e.g., the capacitor contact made of a metal silicide material). A capacitor body 1145 including a dielectric material (e.g., a high-k material) can be deposited on at least part of surfaces of the first electrode 1144 followed by the deposition of a second electrode 1143. In other words, the capacitor body 1145 is between the first electrode 1144 and the second electrode 1143, where the capacitor body 1145 at least partially covers the first electrode 1144, and the second electrode 1143 at least partially covers the capacitor body 1145. The second electrode 1143 can include one or more metallic layers that are stacked together. In some examples, e.g., as illustrated in FIG. 2E, the second electrode 1143 is formed by depositing a first metallic layer 1143a (e.g., TiN) on surface of the capacitor body 1145 and a second metallic layer 1143b (e.g., SiGe) on the first metallic layer 1143a. One or more supporting structures 1150 can be extending along X axis and distributed between the first electrodes 1144 and the second electrodes 1143, and/or between first electrodes 1144 of two adjacent capacitors 1128, e.g., as illustrated in FIG. 2E.

In some implementations, each first electrode 1144 is coupled to the first terminal 1138 of a respective vertical transistor 1126 in the same DRAM cell via a capacitor contact while all second electrodes are coupled to a common plate 1146 coupled to the ground, e.g., a common ground.

It is understood that the structure and configuration of a capacitor 1128 are not limited to the example in FIG. 2E and may include any suitable structure and configuration, such as a pillar capacitor, a cup capacitor, a planar capacitor, a stack capacitor, a multi-fins capacitor, a cylinder capacitor, a trench capacitor, or a substrate-plate capacitor. In some implementations, the capacitor body 1145 includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 1128 may be a ferroelectric capacitor used in a FRAM cell, and the capacitor body 145 may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

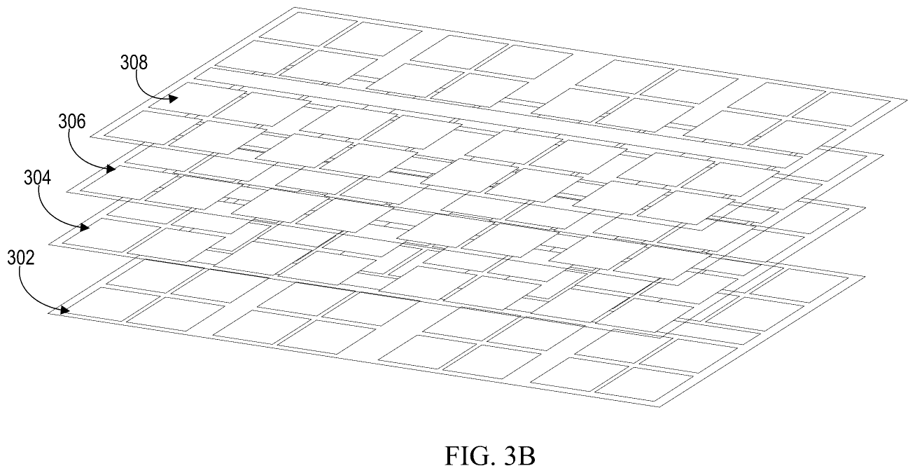

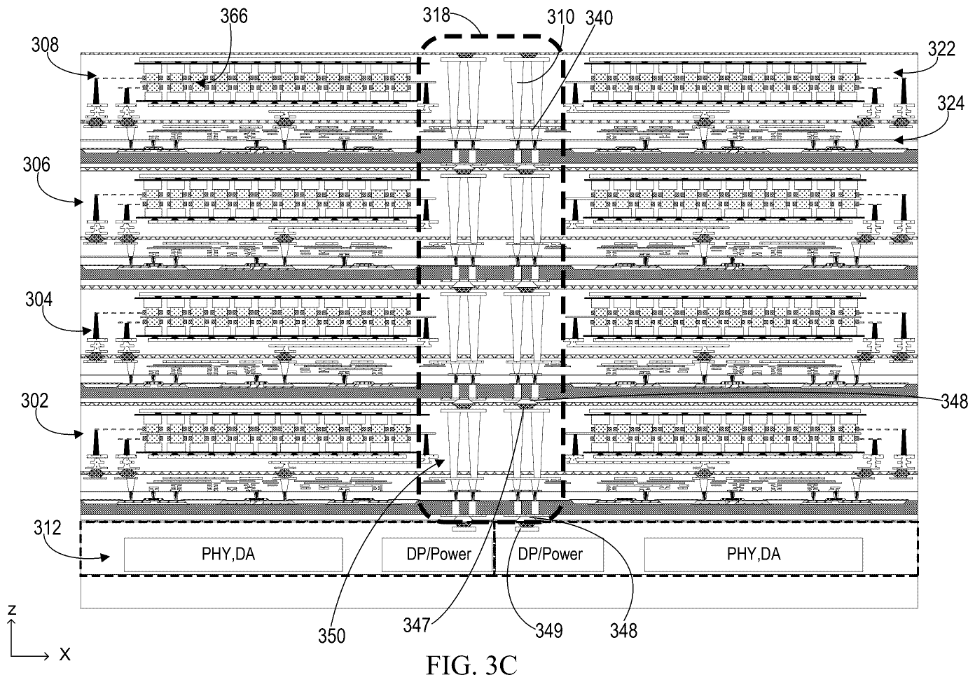

FIG. 3A illustrates a schematic diagram of stacking two memory dies. FIG. 3B illustrates a schematic diagram of a semiconductor device 300 with a plurality of stacked memory dies. FIG. 3C illustrates a cross-sectional view of the semiconductor device 300 of FIG. 3B.

In some implementations, a semiconductor device includes a plurality of memory dies. For example, as illustrated in FIG. 3A, two memory dies can be stacked together. Each memory die can be implemented as the memory die 200 of FIGS. 2A-2D. As noted above, a memory die 200 can include a first semiconductor structure 202 with two memory layers (e.g., the upper memory layer 236-U and the lower memory layer 236-L of FIG. 2B) and a second semiconductor structure 204 (e.g., a control structure). This configuration can be referred to as a 2A1C configuration in the present disclosure. Within each memory die, the control circuit 284 in the second semiconductor structure 204 can be configured to control the two memory layers in the first semiconductor structure 202. Different memory dies 200 can be electrically coupled to one another through corresponding pad-out structures (e.g., first pad-out structures 247, second pad-out structures 248 of FIG. 2B).

As illustrated in FIGS. 3B and 3C, in some implementations, a semiconductor device 300 includes four memory dies 302, 304, 306, 308 that are stacked on a base die 312. The semiconductor device 300 can be implemented as the semiconductor device 100 of FIG. 1A. The memory dies 302, 304, 306, 308 can be the memory dies 102, 104, 106, 108, respectively. Each of the memory dies 302, 304, 306, 308 can be implemented as the memory die 200 of FIGS. 2A-2D. Each of the memory dies 302, 304, 306, 308 can include a 2A1C configuration. While the semiconductor device 300 has been illustrated as having four memory dies, any other number of memory dies can be implemented, e.g., 1 (e.g., as illustrated in FIG. 2B), 2 (e.g., as illustrated in FIG. 3A), 3, 5, 6, or 10.

In some implementations, the plurality of memory dies are stacked together through hybrid bonding, as described above in reference to FIGS. 1A and 2A-2D. As described above, each memory die can include first pad-out structures 347 on a surface of the first semiconductor structure and second pad-out structures 348 on a surface of the second semiconductor structure. The plurality of memory dies can be stacked together with first pad-out structures 347 of a memory die being in contact with corresponding second pad-out structures 348 of an adjacent memory die. The plurality of memory dies can be stacked on the base die 312 with a base pad-out structure 349 being in contact with a corresponding first or second pad-out structure. As illustrated in FIG. 3C, the base pad-out structure 349 can be in contact with a corresponding second pad-out structure 348. The first pad-out structures 347, the second pad-out structures 348 and the base pad-out structures 349 can be collectively referred to as pad-out structures in the present disclosure. In some implementations, the pad-out structures include solder balls, micro-bumps, pillars, or any other suitable bonding techniques.

In some implementations, the via regions 318 of the memory dies 302, 304, 306, 308 are stacked along Z direction, as illustrated in FIG. 3C. In other words, the via regions 318 of different memory dies can be substantially aligned such that an electrical routing between via structures 350 of different memory dies can be reduced. The via structures 350 can be implemented as the via structures 250 of FIG. 2B. The via region 318 can be implemented as the via region 118 of FIG. 1A, or the via region 208 of FIGS. 2A-2D. Multiple via structures 350 can be electrically coupled to one another through pad-out structures of each memory die, and the via structures 350 can be configured to transfer electrical signals between the base die 312 and a corresponding memory die. The pad-out structures may be implemented as the conductive terminals 164, 154, 172, 174, 176 of FIG. 1A. For brevity, detailed descriptions of content overlapping with those of FIGS. 1A and 2A-2D are omitted here.

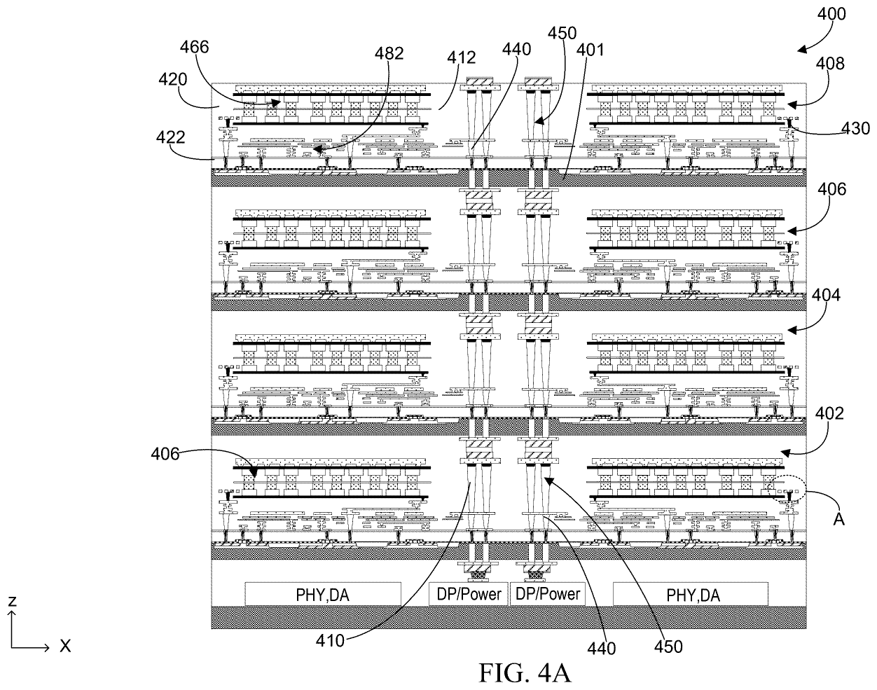

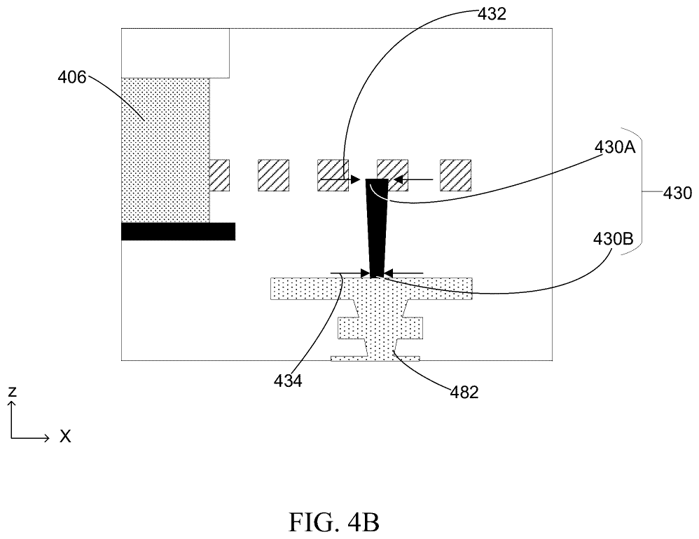

FIG. 4A illustrates another example of a semiconductor device 400 according to one or more implementations of the present disclosure. FIG. 4B illustrates an enlarged view of a region A of the semiconductor device 400 of FIG. 4A. The semiconductor device 400 differs from the semiconductor device 300 primarily in the structure of a memory die. As illustrated in FIG. 4A, instead of fabricating first and second semiconductor structures (e.g., the first and second semiconductor structures 202, 204 of FIG. 2B) separately and bonding them together to form a memory die, each memory die 402, 404, 406, 408 in the semiconductor device 400 can be formed in a single semiconductor structure. In other words, a first semiconductor structure 420 and a second semiconductor structure 422 in a memory die (e.g., the memory die 408) can form an integral part. For example, the first semiconductor structure 420 and the second semiconductor structure 422 are manufactured sequentially on a same substrate 401. Therefore, the memory array 466 of the first semiconductor structure 420 can be directly formed on the interconnection structure 482 of the second semiconductor structure 422 on a front side of the substrate 401.

In some implementations, the memory array 466 is coupled to the interconnection structure 482 through one or more conductive vias 430. Referring to FIG. 4B, in some implementations, the conductive via 430 has a first end 430A coupled to the memory array 466 and a second end 430B coupled to the interconnection structure 482. A size 432 of the first end 430A of the conductive via 430 along X direction can be greater than a size 434 of the second end 430B of the conductive via 430 along the same direction. This feature can be different from a combined contact structure 260 (e.g., an annealed bonding contact) at the bonding interface between the first semiconductor structure 202 and the second semiconductor structure 204 of the memory die 200. Referring back to FIG. 2B, the combined contact structure 260 can have a size that first gradually increase from one end toward the bonding interface, and then gradually decreases towards the other end.

Forming each of the memory dies 402, 404, 406, 408 can involve sequentially forming the following components on a substrate 401: control circuits 284, an interconnection structure 482, and memory arrays 466. Forming the memory arrays 466 can involve depositing at least one dielectric layer 412 on the interconnection structure 482 and then forming memory arrays 466 in the dielectric layers 412. In some implementations, each transistor in the memory arrays 466 include a semiconductor body that is formed using IGZO, IGSO, or a combination thereof. Therefore, a silicon substrate may not be needed in the formation of the memory arrays 466.

Despite the difference in the manufacturing process of a memory die, the memory arrays 466 and via structures 450 (including the first via structures 440) can be substantially similar to those in the memory die 200 of FIGS. 2A-2D. For brevity, detailed descriptions of content overlapping with those of FIGS. 2A-3C are omitted here.

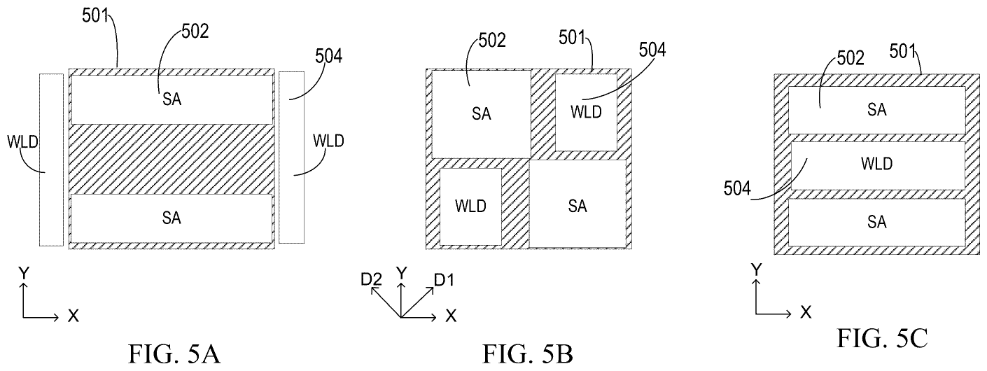

FIGS. 5A-5C illustrate schematic diagrams of examples of layouts of control circuits in a second semiconductor structure. As noted above in reference to FIG. 2B, the control circuit 284 can be disposed directly below the corresponding memory arrays 206 such that an electrical routing from the control circuit 284 to the corresponding memory arrays 206 can be reduced, thereby reducing manufacturing costs and enhancing device performance. As illustrated in FIGS. 5A-5C, the region 501 can refer to a physical region that is disposed below the corresponding memory array 206. For example, turning briefly back to FIG. 2B, the region 501 can be the region 270 that is below the corresponding first memory array 206-1. The first set of control circuits 284-1 for the first memory array 206-1 can be formed in the region 270.

Returning to FIG. 5A, in some implementations, the sense amplifier (SA) regions 502 are arranged on opposed sides of the region 501 along a lateral direction (e.g., Y direction), while the word line driver (WLD) regions 504 can be arranged on opposite sides of the region 501 along another lateral direction (e.g., X direction). Each SA region 502 can include one or more SAs, while each WLD region 504 can include one or more WLDs. Each SA can be configured to control one or more bit lines, while each WLD can be configured to control one or more word lines.

In some implementations, as illustrated in FIG. 5B, the SA regions 502 are disposed diagonally in the region 501 along a first diagonal direction (e.g., D1 direction), while the WLD regions 504 can be disposed diagonally along a second diagonal direction (e.g., D2 direction) that intersects with the first diagonal direction D1.

In some implementations, as illustrated in FIG. 5C, the WLD regions 504 are arranged in a center portion of the region 501, while the SA regions 502 can be arranged on opposite sides of the WLD regions 504 (e.g., along Y direction).

It is to be noted that FIGS. 5A-5C are for illustration purpose only and not intended to be construed in a limiting sense. Any other suitable arrangement of WLD regions 504 and SA regions 502 can be implemented, e.g., inside the region 501 and/or outside the region 501.

FIGS. 6A-6E illustrate cross-sectional views of an example of a semiconductor device 600 during various stages of a manufacturing process. The semiconductor device 600 can include a memory die 650 and a base die 612 (e.g., as illustrated in FIG. 6E). The memory die 650 can be the memory die 102 of FIG. 1A, the 3D memory die 180 of FIG. 1B, the 3D memory die 181 of FIG. 1C, the memory die 200 of FIGS. 2A-2D, or the memory die 302 of FIG. 3C.

As illustrated in FIG. 6A, a first semiconductor structure 602 and a second semiconductor structure 604 can be separately fabricated. The first semiconductor structure 602 can include a memory array 606 with a shared bit line disposed between an upper memory subarray 616-1 and a lower memory subarray 616-2 along Z direction. The memory array 606 can be formed on a first substrate 601. The second semiconductor structure 604 can include a control circuit 684 configured to control the memory array 606. The control circuit 684 can be formed on a second substrate 661. The first substrate 601 and/or the second substrate 661 can include silicon (e.g., single crystalline silicon, c-Si), silicon-germanium (SiGe), gallium arsenide (GaAs), germanium (Ge), silicon-on-insulator (SOI), or any other suitable materials.

Forming the first semiconductor structure 602 and the second semiconductor structure 604 can involve a plurality of processes including, but not limited to, photolithography, dry/wet etch, thin film deposition, thermal growth, implantation, chemical mechanical polishing (CMP), and any other suitable processes.

In some implementations, forming the second semiconductor structure 604 includes forming first via structures 640 that extend in the interconnection structure 682. Forming first via structures 640 can involve the following process steps: (i) forming a plurality of conductive layers 230 on the control circuit 684, where each conductive layer 630 can include one or more conductive lines 642 that are separated by a dielectric material (e.g., an ILD layer 646); (2) forming an upper dielectric layer that will be used later to form an upper conductive layer 630C on top of the plurality of conductive layers 630; (2) forming a hard mask (e.g., titanium nitride) on the upper ILD layer to define a pattern of supper vias and a pattern of conductive lines; (3) etching to form first via structure holes and trenches for conductive lines, where the first via structure holes extend through the upper ILD layer and at least one conductive layer 630, and the trenches extend in the upper ILD layer; and (4) depositing a conductive material (e.g., tungsten, ruthenium) into the first via structure holes and trenches to form first via structures 640 and the upper conductive layer 630C, respectively.

In some implementations, the plurality of conductive layers 630 include a first conductive layer 630A (e.g., M1) and a second conductive layer 630B (e.g., M2) that is stacked on M1. The upper ILD layer can be the third ILD layer (e.g., ILD3). The upper conductive layer 630C can be the third conductive layer (e.g., M3). The first via structure holes can extend from an upper surface of the ILD3 to the upper surface of M1. The first via structures 640 and M3 can be formed together. Therefore, the first via structures 640 and M3 can have the same material (e.g., ruthenium).

In some implementations, the first via structures 640 are formed in both the device region 607 and the via region 608, as described above in reference to FIGS. 2A-2D. In some implementations, the second segment 620B of the through-via structure 620 are also formed, which is connected to the first via structures 640, as illustrated in FIG. 6A. The second segment 620B of the through-via structure 620 can be formed before forming first via structures 640. The second segment 620B of the through-via structure 620 can include but not limited to, TiN, TaN, Al, W, Cu, doped-polysilicon, silicides, or any combination thereof. In the present disclosure, a combination of the first via structures 640 and the second segment 620B of the through-via structure 620 can be referred to as a first part 620-1 of the through-via structure 620.

With continued reference to FIG. 6A, the first semiconductor structure 602 and the second semiconductor structure 604 can be bonded to couple the control circuit 684 to the memory array 606. In some implementations, the first semiconductor structure 602 and the second semiconductor structure 604 are bonded using hybrid bonding, as described above. In some implementations, the first semiconductor structure 602 and the second semiconductor structure 604 are bonded using solder balls, pillars, or micro-bumps.

As illustrated in FIG. 6B, the second substrate 661 of the second semiconductor structure 604 can be thinned, e.g., through a polishing process to reduce the thickness. The polishing process can include, but not limited to, chemical mechanical polishing (CMP), mechanical polishing, electrochemical polishing, ultrasonic polishing, or any combination thereof.

As illustrated in FIG. 6C, the third segment 620C of the through-via structure 620 can be formed that extend through the thinned second substrate 661. The third segment 620C of the through-via structure 620 can be referred to as a second part 620-2 of the through-via structure 620 in the present disclosure. The second part 620-2 of the through-via structure 620 can be stacked on the first part 620-1 of the through-via structure 620 along Z direction. The second part 620-2 of the through-via structure 620 can include, but not limited to, TiN, TaN, Al, W, Cu, doped-polysilicon, silicides, or any combination thereof.

Second pad-out structures 648 can be formed on the backside of the second substrate 661 and coupled to the second part 620-2 of the through-via structure 620. The second pad-out structures 648 can extend through a dielectric layer 649 that is deposited on the backside of the second substrate 661. The second pad-out structures 648 can be configured to transfer electrical signal from and to the second semiconductor structure 604. The second pad-out structures 648 can include, but not limited to, TiN, TaN, Al, W, Cu, doped-polysilicon, silicides, or any combination thereof.

As illustrated in FIG. 6D, the memory die 650 can then bonded onto a base die 612. The base die 612 can be the base die 112 of FIG. 1A, or the base die 312 of FIG. 3C. The base die 612 can include at least one of direct access (DA) ports, PHY interface and/or power supply unit. The base die 612 can also include base pad-out structures 688 on the upper surface of the base die 612.

Bonding the memory die 650 with the base die 612 can involve aligning the second pad-out structures 648 of the second semiconductor structure 604 to the base pad-out structures 688 of the base die 612 and then annealing the second pad-out structures 648 and the base pad-out structure 688 to form Cu-to-Cu bonding. The control circuit 684 in the second semiconductor structure 604 can be electrically coupled to the base die 612 through corresponding second pad-out structures 648 and the base pad-out structure 688.

As illustrated in FIG. 6E, the first substrate 601 can be removed. The second via structure 610 can be formed that extends through the first semiconductor structure 602. Forming second via structure 610 can involve etching a second via hole through the first semiconductor structure 602, following by depositing a conductive material into the second via hole. The conductive material of the second via structure 610 including, but not limited to W, Co, Cu, Al, TiN, TaN, polysilicon, or any combination thereof. The first via structure 640 and the second via structure 610 can have the same or different conductive materials.

In some implementations, as illustrated in FIG. 6E, the second via structure 610 may extend into the second semiconductor structure 604 and be in contact with the interconnection structure 682 of the second semiconductor structure 604. Therefore, the first via structure 640 and the second via structure 610 can be coupled through the interconnection structure 682 of the second semiconductor structure 604.

In some implementations, the second via structure 610 extends within the first semiconductor structure 602 and connects to a first contact structure 662 at a lower surface of the first semiconductor structure 602. The first contact structure 662 of the first semiconductor structure 602 can then be in contact with a corresponding second contact structure 664 at an upper surface of the second semiconductor structure 604. The second contact structure 664 can be coupled to the first via structure 640. Therefore, the first via structure 640 and the second via structure 610 can be coupled through first and second contact structures 662, 664 at the bonding interface.

With continued reference to FIG. 6E, the connection structure 613 and first pad-out structure 647 can be formed on the second via structures 610. The first pad-out structures 647 of the first semiconductor structure 602 can be formed using similar processes as the second pad-out structures 648 of the second semiconductor structure 604, as described above. The first pad-out structures 647 can be coupled to the second pad-out structures 648 through the second via structure 610 and first via structure 640.

At this process stage, the first semiconductor structure 602 can be the first semiconductor structure 182 of FIGS. 1A and 1B, the first semiconductor structure 202 of FIGS. 2A-2D, or the first semiconductor structure 322 of FIG. 3C. The second semiconductor structure 604 can be the second semiconductor structure 184 of FIGS. 1A and 1B, the second semiconductor structure 204 of FIGS. 2A-2D, or the second semiconductor structure 324 of FIG. 3C. The first semiconductor structure 602 and the second semiconductor structure 604 can form the memory die 650. The memory die 650 and the base die 612 can form the semiconductor device 600.

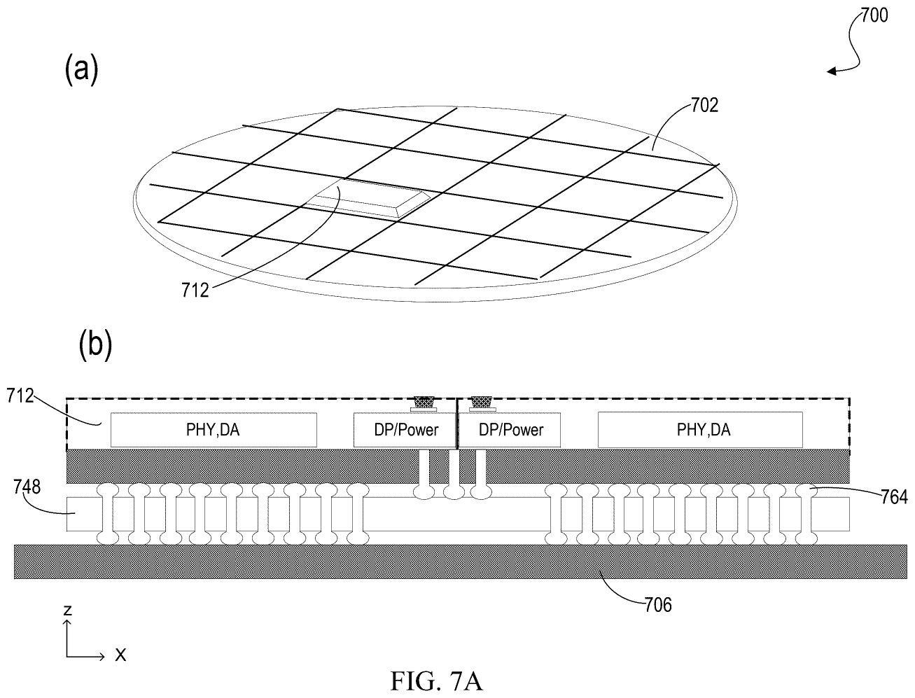

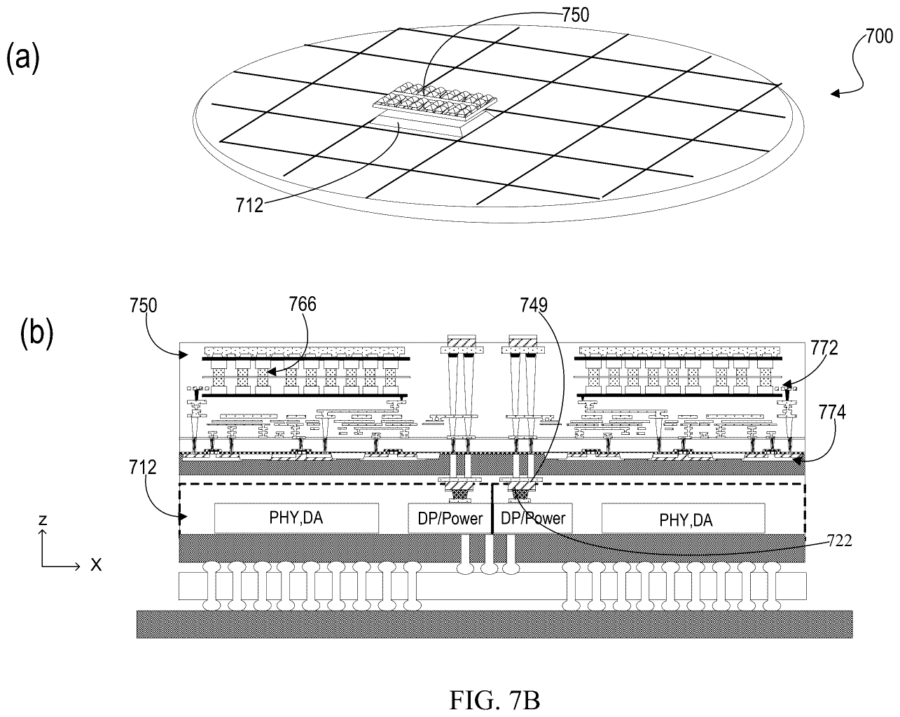

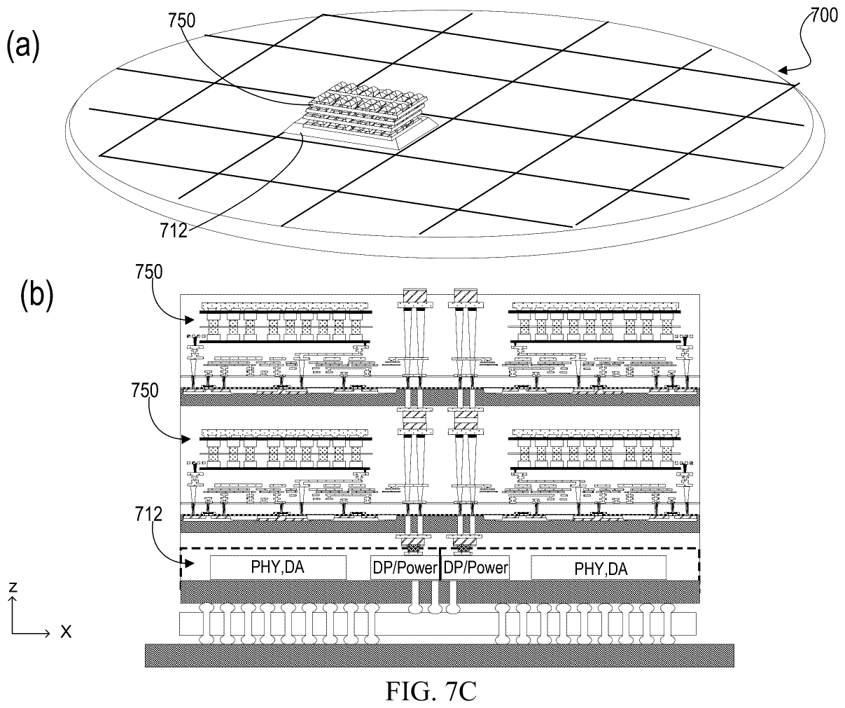

FIGS. 7A-7C illustrate a die to wafer bonding process of forming a chip package 700. As illustrated in diagram (a) of FIG. 7A, base dies 712 can be provided in a wafer configuration. The wafer 702 can include a plurality of base dies 712. The wafer 702 can be stacked over an interposer 748 (e.g., the interpose 148 of FIG. 1A). The interposer 748 can have surface bonding contacts 764 that are coupled to the bonding contacts of the base die 712 to form an electrical communicational channel. In some implementations, the interposer 748 is stacked over a substrate 706.

As illustrated in FIG. 7B, a single memory die 750 can be stacked over a respective base die 712. The memory die 750 can be the memory die 102 of FIG. 1A, the 3D memory die 180 of FIG. 1B, the 3D memory die 181 of FIG. 1C, the memory die 200 of FIGS. 2A-2D, the memory die 302 of FIG. 3C, or the memory die 650 of FIG. 6E. Stacking the memory die 750 over the base die 712 can involve bonding the contact structures (e.g., pad-out structures 749) of the memory die 750 to corresponding contact structures (e.g., base pad-out structures 722) of the base die 712. As the base die 712 is provided in a wafer configuration, bonding the memory die 750 to the base die 712 can be referred to a die to wafer bonding process in the present disclosure.

As illustrated in FIG. 7C, after the first memory die 750 is stacked over the base die 712, additional memory dies 750 can be sequentially stacked over the first memory die 750 along Z direction, e.g., to increase storage capacity. Diagram (a) of FIG. 7C shows four memory dies 750 can be stacked on the base die 712, and diagram (b) of FIG. 7C shows two memory dies 750 can be stacked on the base die 712. It is to be noted that examples in FIG. 7C are not intended to be construed in a limiting sense. Any other number of memory dies 750 can be implemented in the chip package 700.

After a plurality of memory dies 750 are stacked onto the base die 712, the wafer can be diced into multiple pieces, with each piece including a single base die 712 and the plurality of memory dies 750 that are vertically stacked on the base die 712. Each unit can be the semiconductor device 100 of FIG. 1A. In some implementations, the dicing process includes, without limitation to, laser dicing, blade dicing, plasma dicing, mechanical punch dicing, or laser assisted water jet dicing.

The die-to-wafer bonding techniques can provide several advantages. For example, know good memory dies 750 (e.g., pretested, functional dies) can be used in forming a chip package 700 by sequentially stacking them vertically on a base die 712. Attaching only good memory dies 750 to a wafer during the bonding process can significantly improve yield of the chip package 700 compared to wafer-to-wafer bonding, as wafers may include defective dies. Die-to-wafer bonding can allow heterogeneous integration where stacked dies can be different. For example, the stacked dies can include a memory die 750 and a controller. In another example, the stacked dies can include a DRAM die and a NAND die.

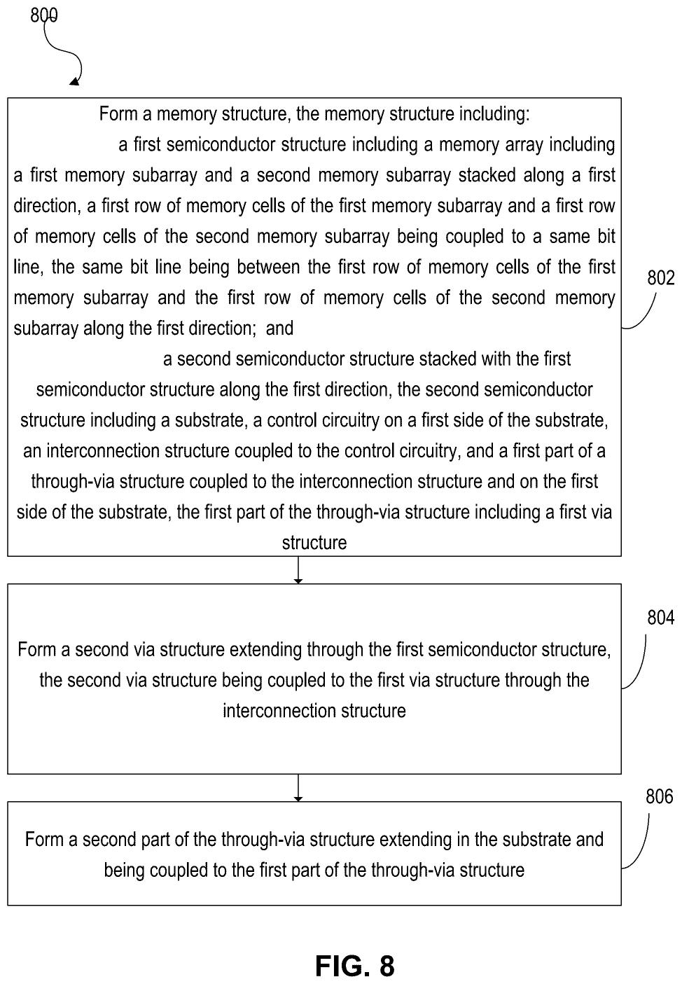

FIG. 8 illustrates a flow chart of an example of a method 800 of forming a semiconductor device. The semiconductor device can be, e.g., the semiconductor device 100 of FIG. 1A, the 3D memory die 180 of FIG. 1B, the 3D memory die 181 of FIG. 1C, the memory die 200 of FIGS. 2A-2D, the semiconductor device 300 of FIG. 3C, the semiconductor device 400 of FIG. 4A, the semiconductor device 600 of FIGS. 6A-6E, or the chip package 700 of FIGS. 7A-7C.

At step 802, a memory device is formed. The memory device includes: (i) a first semiconductor structure that includes a memory array, where the memory array includes a first memory subarray and a second memory subarray stacked along a first direction, a first row of memory cells of the first memory subarray and a first row of memory cells of the second memory subarray are coupled to a same bit line, and the same bit line is between the first row of memory cells of the first memory subarray and the first row of memory cells of the second memory subarray along the first direction; and (ii) a second semiconductor structure stacked with the first semiconductor structure along the first direction, where the second semiconductor structure includes a substrate, a control circuitry on a first side of the substrate, an interconnection structure coupled to the control circuitry, and a first part of a through-via structure coupled to the interconnection structure and on the first side of the substrate. The first part of the through-via structure includes a first via structure. The memory device can be, e.g., any one of the memory dies 102, 104, 106, 108 of FIG. 1A, the 3D memory die 180 of FIG. 1B, the 3D memory die 181 of FIG. 1C, the memory die 200 of FIGS. 2B-2D, any one of the memory dies 302, 304, 306, 308 of FIG. 3C, any one of memory dies 402, 404, 406, 408 of FIG. 4A, the memory die 650 of FIGS. 6A-6E, or the memory die 750 of FIGS. 7A-7C. The first semiconductor structure can be, e.g., the first semiconductor structure 182 of FIGS. 1B and 1C, the first semiconductor structure 202 of FIGS. 2B-2D and 3A, the first semiconductor structure 322 of FIG. 3C, the first semiconductor structure 420 of FIG. 4A, the first semiconductor structure 602 of FIGS. 6A-6E, or the first semiconductor structure 772 of FIGS. 7B and 7C. The memory array can be, e.g., the memory array 206 of FIGS. 2A-2D, the memory array 366 of FIG. 3C, the memory array 466 of FIG. 4A, the memory array 606 of FIGS. 6A-6E, or the memory array 766 of FIGS. 7B-7C. The first memory subarray can be, e.g., the first memory subarray 216-1 of FIGS. 2B-2D. The second memory subarray can be, e.g., the second memory subarray 216-2 of FIGS. 2B-2D. The first row of memory cells of the first memory subarray can be, e.g., the first row 216-1A of first memory cells of the first memory subarray 216-1 of FIGS. 2B-2D. The first row of memory cells of the second memory subarray can be, e.g., the first row 216-2A of first memory cells of the second memory subarray 216-2 of FIGS. 2B-2D. The bit line can be, e.g., the bit line 223 of FIG. 2B. The second semiconductor structure can be, e.g., the second semiconductor structure 184 of FIGS. 1B and 1C, the second semiconductor structure 204 of FIGS. 2B-2D and 3A, the second semiconductor structure 324 of FIG. 3C, the second semiconductor structure 422 of FIG. 4A, the second semiconductor structure 604 of FIGS. 6A-6E, or the second semiconductor structure 774 of FIGS. 7B and 7C. The substrate can be, e.g., the substrate 201 of FIGS. 2B-2D, or the second substrate 661 of FIGS. 6A-6E. The interconnection structure can be, e.g., the interconnection structure 282 of FIGS. 2B-2D, the interconnection structure 482 of FIG. 4A, or the interconnection structure 682 of FIGS. 6A-6E. The through-via structure can be, e.g., the through-via structure 220 of FIGS. 2B-2D, or the through-via structures 620 of FIGS. 6A-6E. The first via structures can be, e.g., the first via structure 240 of FIGS. 2B-2D, the first via structure 340 of FIG. 3C, the first via structure 440 of FIG. 4A, or the first via structure 640 of FIGS. 6A-6E.

At step 804, a second via structure is formed extending through the first semiconductor structure. The second via structure is coupled to the first via structure through the interconnection structure. The second via structure can be, e.g., the second via structure 210 of FIGS. 2B-2D, the second via structure 310 of FIG. 3C, the second via structure 410 of FIG. 4A, or the second via structure 610 of FIG. 6E.

At step 806, forming a second part of the through-via structure extending in the substrate and being coupled to the first part of the through-via structure. The first part of the through-via structure can be, e.g., the first part of through-via structure 620-1 of FIGS. 6A-6E. The second part of the through-via structure can be, e.g., second part of the through-via structure 620-2 of FIGS. 6C-6E.

In some implementations, the method 800 includes: forming a pad-out structure on a second side of the substrate of the second semiconductor structure and coupled to the first via structure, the memory array of the first semiconductor structure being coupled to the pad-out structure through the first via structure and the second via structure; providing a base structure including a plurality of base dies, a base die of the plurality of base dies including a circuitry and a base pad-out structure coupled to the circuitry; and stacking the memory device over the base die with the pad-out structure being in contact with the base pad-out structure. The base structure can be, e.g., the wafer 702 of FIGS. 7A-7C. The base pad-out structure can be, e.g., the base pad-out structure 349 of FIG. 3C, the base pad-out structures 688 of FIGS. 6D-6E, or the base pad-out structure 722 of FIGS. 7B and 7C. The pad-out structures can be, e.g., the second pad-out structures 248 of FIGS. 2B-2D, the second pad-out structure 348 of FIG. 3C, the second pad-out structures 648 of FIGS. 6C-6E, or the second pad-out structures 749 of FIGS. 7B-7C.

In some implementations, the memory device is a first memory device. The method 800 includes: forming a plurality of memory devices including the first memory device, where the plurality of memory devices includes first via structures and second via structures; and stacking the plurality of memory devices sequentially on the base die along the first direction. The plurality of memory devices are coupled to one another through first via structures and corresponding second via structures. The plurality of memory devices are coupled to the circuitry of the base structure through the first via structures, the second via structures, and the base pad-out structure, as illustrated in FIGS. 1A-7C.

In some implementations, forming the memory device includes: forming the second semiconductor structure including one or more first contact structures through a first dielectric layer and isolated from each other in the first dielectric layer; forming the first semiconductor structure including one or more second contact structures through a second dielectric layer and isolated from each other in the second dielectric layer; and stacking the second semiconductor structure and the first semiconductor structure along the first direction. The first dielectric layer is in contact with the second dielectric layer. At least one of the one or more first contact structures is in contact with a corresponding one of the one or more second contact structures. The memory array is coupled to the control circuitry through at least one of the one or more first contact structures and at least one of the one or more second contact structures, as described above in reference to FIGS. 1A-7C.

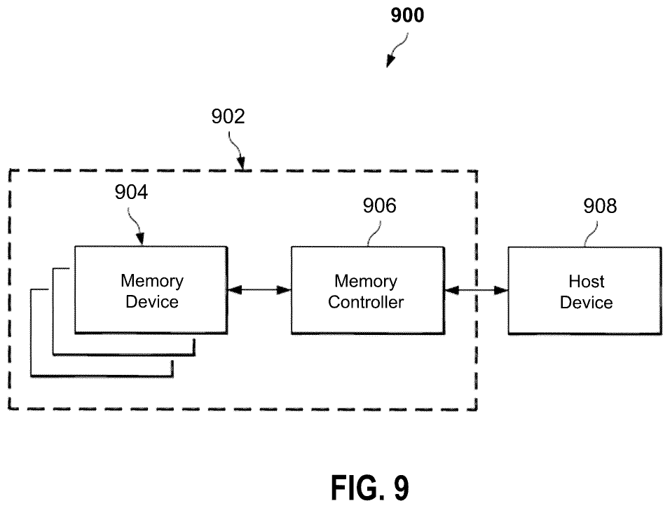

FIG. 9 illustrates a block diagram of a system 900 having one or more semiconductor devices (e.g., memory devices), according to one or more implementations of the present disclosure. The system 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, the system 900 can include a host device 908 and a memory system 902 having one or more 3D memory devices 904 and a memory controller 906. Host device 908 can include a processor of an electronic device, such as a central processing unit (CPU), or a system-on-chip (SoC), such as an application processor (AP). Host device 908 can be configured to send or receive data to or from the one or more 3D memory devices 904.

A 3D memory device 904 can be any 3D memory device disclosed herein, such as any one of the memory dies 102, 104, 106, 108 of FIG. 1A, the 3D memory die 180 of FIG. 1B, the 3D memory die 181 of FIG. 1C, the memory die 200 of FIGS. 2B-2D, any one of the memory dies 302, 304, 306, 308 of FIG. 3C, any one of memory dies 402, 404, 406, 408 of FIG. 4A, the memory die 650 of FIGS. 6A-6E, or the memory die 750 of FIGS. 7A-7C.

In some implementations, a 3D memory device 904 includes a NAND Flash memory. Memory controller 906 (a.k.a., a controller circuit) is coupled to 3D memory device 904 and host device 908. Consistent with implementations of the present disclosure, 3D memory device 904 can include a plurality of conductive interconnections through a cover layer that are in contact with conductive pads in a conductive pad layer, and memory controller 906 can be coupled to 3D memory device 904 through at least one of the plurality of conductive interconnections. Memory controller 906 is configured to control 3D memory device 904. For example, memory controller 906 may be configured to operate a plurality of channel structures via word lines. Memory controller 906 can manage data stored in 3D memory device 904 and communicate with host device 908.

In some implementations, memory controller 906 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 906 can be configured to control operations of 3D memory device 904, such as read, erase, and program (or write) operations. Memory controller 906 can also be configured to manage various functions with respect to the data stored or to be stored in 3D memory device 904 including, but not limited to bad-block management, garbage collection, logical-to-physical address conversion, wear leveling, etc. In some implementations, memory controller 906 is further configured to process error correction codes (ECCs) with respect to the data read from or written to 3D memory device 904. Any other suitable functions may be performed by memory controller 906 as well, for example, formatting 3D memory device 904.

Memory controller 906 can communicate with an external device (e.g., host device 908) according to a particular communication protocol. For example, memory controller 906 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 906 and one or more 3D memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 9, memory controller 906 and a single 3D memory device 904 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. in addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device 300 is formed, and therefore the semiconductor device 300 is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion 921 including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, conductive lines 942, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device 300. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 90%, 90%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device 300 with vertically oriented strings of memory cell transistor 926s (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. in addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. in some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first semiconductor structure comprising a memory array, the memory array including a first memory subarray and a second memory subarray stacked along a first direction, a first row of memory cells of the first memory subarray and a first row of memory cells of the second memory subarray being coupled to a same bit line, the same bit line being between the first row of memory cells of the first memory subarray and the first row of memory cells of the second memory subarray along the first direction;
a second semiconductor structure stacked with the first semiconductor structure along the first direction, wherein the second semiconductor structure comprises a control circuitry coupled to the memory array, an interconnection structure, a pad-out structure, and a first via structure coupling the interconnection structure to the pad-out structure, the control circuitry being between the interconnection structure and the pad-out structure along a first direction; and
a second via structure extending through the first semiconductor structure, the second via structure being coupled to the pad-out structure of the second semiconductor structure through the first via structure and the interconnection structure.

2. The semiconductor device of claim 1, wherein the first memory subarray comprises a plurality of first memory cells, the second memory subarray comprises a plurality of second memory cells, a first memory cell of the plurality of first memory cells is aligned with a corresponding second memory cell of the plurality of second memory cells along the first direction, each of the first memory cell and the corresponding second memory cell extends along the first direction and comprises a transistor and a capacitor, and the transistor is closer to the same bit line than the capacitor along the first direction.

3. The semiconductor device of claim 2, wherein the transistor comprises a semiconductor body extending along the first direction, and the semiconductor body comprises a metal oxide semiconductor material.

4. The semiconductor device of claim 1, wherein the second via structure comprises a plurality of portions each extending along the first direction, the plurality of portions are arranged along a second direction different from the first direction and separated by an inter-dielectric material, and the interconnection structure comprises a plurality of conductive lines, and
wherein first ends of the plurality of portions of the second via structure are coupled to a same connection structure, and second ends of the plurality of portions of the second via structure are coupled to a same conductive line of the plurality of conductive lines of the interconnection structure.

5. The semiconductor device of claim 4, wherein a pitch of the plurality of portions of the second via structure is smaller than or equal to 1 μm along the second direction.

6. The semiconductor device of claim 4, wherein a size of a portion of the plurality of portions of the second via structure is smaller than or equal to 0.5 μm along the second direction.

7. The semiconductor device of claim 1, wherein the interconnection structure comprises a first conductive layer, at least one second conductive layer, and a third conductive layer, the at least one second conductive layer being between the first conductive layer and the third conductive layer along the first direction,
wherein a first end of the first via structure is connected to the first conductive layer, a second end of the first via structure is connected to the third conductive layer, and a conductive material of the first via structure is isolated from the at least one second conductive layer by a dielectric material.

8. The semiconductor device of claim 7, wherein a size of the first via structure is smaller than or equal to 0.5 μm along a second direction.

9. The semiconductor device of claim 1, wherein the memory array of the first semiconductor structure is on the interconnection structure of the second semiconductor structure, and the memory array is coupled to the interconnection structure through a conductive via, and
wherein the conductive via has a first end coupled to the memory array and a second end coupled to the interconnection structure, and a size of the first end of the conductive via along a second direction different from the first direction is greater than a size of the second end of the conductive via.

10. The semiconductor device of claim 1, wherein the second semiconductor structure is coupled to the first semiconductor structure through at least one contact structure, and the at least one contact structure comprises at least one of a bonding pad, a solder bump, a micro-bump, or a pillar.

11. A semiconductor device, comprising:
a plurality of memory devices sequentially stacked along a first direction,
wherein a memory device of the plurality of memory devices comprises a first pad-out structure at a first surface and a second pad-out structure at a second surface opposite to the first surface along a first direction,
wherein the memory device comprises:
a first semiconductor structure comprising: (i) a memory array including a first memory subarray and a second memory subarray stacked along the first direction, a first row of memory cells of the first memory subarray and a first row of memory cells of the second memory subarray being coupled to a same bit line, the same bit line being between the first row of memory cells of the first memory subarray and the first row of memory cells of the second memory subarray along the first direction, and (ii) the first pad-out structure; and
a second semiconductor structure stacked with the second semiconductor structure along the first direction, wherein the second semiconductor structure comprises a control circuitry coupled to the memory array, an interconnection structure, and the second pad-out structure,
wherein the plurality of memory devices are coupled to one another with first pad-out structures being in contact with corresponding second pad-out structures.

12. The semiconductor device of claim 11, wherein the second semiconductor structure comprises a first via structure coupling the interconnection structure to the second pad-out structure,
wherein the memory device of the plurality of memory devices comprises: a second via structure extending through the first semiconductor structure and a portion of the second semiconductor structure, the second via structure being coupled to the first via structure through the interconnection structure, and
wherein the first pad-out structure is coupled to the corresponding second pad-out structure through the first via structure and the second via structure.

13. The semiconductor device of claim 12, wherein the second via structure comprises a plurality of portions each extending along the first direction, the plurality of portions are arranged along a second direction different from the first direction and separated by an inter-dielectric material, the interconnection structure comprises a plurality of conductive lines, and
wherein first ends of the plurality of portions of the second via structure are coupled to a same connection structure, and second ends of the plurality of portions of the second via structure are coupled to a same conductive line of the plurality of conductive lines of the interconnection structure.

14. The semiconductor device of claim 11, wherein the first memory subarray comprises a plurality of first memory cells, the second memory subarray comprises a plurality of second memory cells, a first memory cell of the plurality of first memory cells is aligned with a corresponding second memory cell of the plurality of second memory cells along the first direction, each of the first memory cell and the corresponding second memory cell extends along the first direction and comprises a transistor and a capacitor, and the transistor is closer to the same bit line than the capacitor along the first direction.

15. The semiconductor device of claim 11, wherein the second semiconductor structure comprises one or more first contact structures through a first dielectric layer along the first direction and isolated from each other in the first dielectric layer, and the first semiconductor structure comprises one or more second contact structures through a second dielectric layer along the first direction and isolated from each other in the second dielectric layer,
wherein, along the first direction, the first dielectric layer is in contact with the second dielectric layer, and at least one of the one or more first contact structures is in contact with a corresponding one of the one or more second contact structures, and
wherein the memory array is coupled to the control circuitry through at least one of the one or more first contact structures and at least one of the one or more second contact structures.

16. The semiconductor device of claim 11, comprising:
a base structure comprising a circuitry and a base pad-out structure coupled to the circuitry,
wherein the plurality of memory devices are sequentially stacked over the base structure along the first direction, and the plurality of memory devices are coupled to the circuitry of the base structure through the first pad-out structures, the second pad-out structures and the base pad-out structure.

17. A method, comprising:
forming a memory device, the memory device comprising:
a first semiconductor structure comprising a memory array including a first memory subarray and a second memory subarray stacked along a first direction, a first row of memory cells of the first memory subarray and a first row of memory cells of the second memory subarray being coupled to a same bit line, the same bit line being between the first row of memory cells of the first memory subarray and the first row of memory cells of the second memory subarray along the first direction; and
a second semiconductor structure stacked with the first semiconductor structure along the first direction, the second semiconductor structure comprising a substrate, a control circuitry on a first side of the substrate, an interconnection structure coupled to the control circuitry, and a first part of a through-via structure coupled to the interconnection structure and on the first side of the substrate, the first part of the through-via structure comprising a first via structure;
forming a second via structure extending through the first semiconductor structure, the second via structure being coupled to the first via structure through the interconnection structure; and
forming a second part of the through-via structure extending in the substrate and being coupled to the first part of the through-via structure.

18. The method of claim 17, comprising:
forming a pad-out structure on a second side of the substrate of the second semiconductor structure and coupled to the first via structure, the memory array of the first semiconductor structure being coupled to the pad-out structure through the first via structure and the second via structure;
providing a base structure comprising a plurality of base dies, a base die of the plurality of base dies comprising a circuitry and a base pad-out structure coupled to the circuitry; and
stacking the memory device over the base die with the pad-out structure being in contact with the base pad-out structure.

19. The method of claim 18, wherein the memory device is a first memory device, and
wherein the method comprises:
forming a plurality of memory devices including the first memory device, the plurality of memory devices including first via structures and second via structures, and
stacking the plurality of memory devices sequentially on the base die along the first direction, the plurality of memory devices being coupled to one another through first via structures and corresponding second via structures, the plurality of memory devices being coupled to the circuitry of the base structure through the first via structures, the second via structures, and the base pad-out structure.

20. The method of claim 17, wherein forming the memory device comprises:
forming the second semiconductor structure comprising one or more first contact structures through a first dielectric layer and isolated from each other in the first dielectric layer;
forming the first semiconductor structure comprising one or more second contact structures through a second dielectric layer and isolated from each other in the second dielectric layer; and
stacking the second semiconductor structure and the first semiconductor structure along the first direction, the first dielectric layer being in contact with the second dielectric layer, and at least one of the one or more first contact structures being in contact with a corresponding one of the one or more second contact structures,
wherein the memory array is coupled to the control circuitry through at least one of the one or more first contact structures and at least one of the one or more second contact structures.
